(19) United States
(12) Patent Application Publication
(10) Pub. No.: US 2015/0280708 A1
(43) Pub. Date: Oct. 1, 2015

(54) INFORMATION PROCESSING DEVICE, INPUT DEVICE, INFORMATION PROCESSING METHOD, AND PROGRAM

(71) Applicant: Sony Corporation, Tokyo (JP)

(72) Inventors: Tetsuro Goto, Tokyo (JP); Hiroto Kawaguchi, Kanagawa (JP); Takashi Itaya, Kanagawa (JP); Toshio Kano, Kanagawa (JP); Akira Ebisui, Kanagawa (JP)

(73) Assignee: Sony Corporation, Tokyo (JP)

(21) Appl. No.: 14/665,063

(22) Filed: Mar. 23, 2015

(30) Foreign Application Priority Data
Mar. 31, 2014 (JP) 2014-073034

(51) Int. Cl. H03K 17/98

(52) U.S. Cl. CPC H03K 17/98; H03K 2217/0027

(57) ABSTRACT

There is provided an information processing device including a temperature compensation unit configured to correct an operation input value indicating an operation input to each of a plurality of key regions provided on a sheet-like operation member based on ambient temperature of an input device in which the operation input to each of the key regions is detected as a capacitance variation amount of a capacitive element depending on a change in a distance between the key region and the capacitive element, the capacitive element being provided in a manner that the capacitive element corresponds to each of the key regions.

### CROSS REFERENCE TO RELATED APPLICATIONS

This application claims the benefit of Japanese Priority Patent Application JP 2014-073034 filed Mar. 31, 2014, the entire contents of which are incorporated herein by reference.

### BACKGROUND

The present disclosure relates to an information processing device, an input device, an information processing method, and a program.

A keyboard is commonly used as an input device for an information processing device, such as personal computers (PCs). Nowadays a touch panel that is used as a thin keyboard is spreading widely. In the keyboard that employs a touch panel, a GUI component corresponding to each key arranged on the keyboard is displayed on a display surface of the touch panel on which the user can select one or more displayed keys, and thus information associated with the selected key is inputted to the information processing device.

The touch panel is used in various applications. Among them, a sensor element for detecting a contact of an operation object with the touch panel sometimes has temperature dependence characteristics. In this case, the sensitivity of the detection of an operation object with the touch panel is likely to vary depending on the temperature of the operating environment, and thus there is a risk of lack of usability.

Thus, a technique for compensation of temperature depending on temperature of the operating environment in the touch panel has been developed. For example, JP 2009-020006A discloses a technique for obtaining temperature characteristics of impedance of an electrostatic capacitance sensor in advance and for correcting electrostatic capacitance of the electrostatic capacitance sensor by using the obtained temperature characteristics in the electrostatic type touch panel. In addition, for example, JP 2002-169649A discloses a technique for correcting frequency characteristics of an input/output inter-digital transducer (IDT) of a surface acoustic wave using the frequency characteristics of the IDT for temperature compensation in order to cope with a change in velocity of a surface acoustic wave in an ultrasonic type touch panel.

### SUMMARY

However, the techniques disclosed in JP 2009-020006A and JP 2002-169649A are intended to be applied to a typical touch panel, but they are not particularly intended to be applied to the case of using it as a keyboard or like device. When a touch panel is used as a keyboard, for example, it may be assumed that an operation input, which is different from the case of performing continuous and fast keystrokes to a region corresponding to a key, is performed. Thus, when a touch panel is used as a keyboard, the usability in the touch panel may be different from that of other applications. Thus, if the techniques disclosed in JP 2009-020006A and JP 2002-169649A are applied to a keyboard using a touch panel without any change, the usability is not necessarily be improved.

In view of the above circumstances, it is necessary to provide a technology for implementing a higher degree of usability by performing compensation for detection sensitivity of an operation object depending on temperature of the operating environment while considering usability as a keyboard. According to an embodiment of the present disclosure, there is provided a novel and improved information processing device, input device, information processing method, and program, capable of achieving a higher degree of usability.

According to an embodiment of the present disclosure, there is provided an information processing device including a temperature compensation unit configured to correct an operation input value indicating an operation input to each of a plurality of key regions provided on a sheet-like operation member based on ambient temperature of an input device in which the operation input to each of the key regions is detected as a capacitance variation amount of a capacitive element depending on a change in a distance between the key region and the capacitive element, the capacitive element being provided in a manner that the capacitive element corresponds to each of the key regions.

According to another embodiment of the present disclosure, there is provided an input device including a sheet-like operation member that includes a plurality of key regions and is deformable depending on an operation input to the key region, an electrode board that includes at least one capacitive element at a position corresponding to each of the key regions and is capable of detecting an amount of change in a distance between the key region and the capacitive element as a capacitance variance amount of the capacitive element, the amount of change being dependent on the operation input, and a controller configured to correct an operation input value indicating an operation input to the key region based on ambient temperature.

According to still another embodiment of the present disclosure, there is provided an information processing method including correcting, by a processor, an operation input value indicating an operation input to each of a plurality of key regions provided on a sheet-like operation member based on ambient temperature of an input device in which the operation input to each of the key regions is detected as a capacitance variation amount of a capacitive element depending on a change in a distance between the key region and the capacitive element, the capacitive element being provided in a manner that the capacitive element corresponds to each of the key regions.

According to yet another embodiment of the present disclosure, there is provided a program for causing a processor of a computer to execute the function of correcting an operation input value indicating an operation input to each of a plurality of key regions provided on a sheet-like operation member based on ambient temperature of an input device in which the operation input to each of the key regions is detected as a capacitance variation amount of a capacitive element depending on a change in a distance between the key region and the capacitive element, the capacitive element being provided in a manner that the capacitive element corresponds to each of the key regions.

According to one or more of embodiments of the present disclosure, in a keyboard in which a physical pressing amount to a key region is detectable as an operation input value indicating an operation input to the key region, the operation input value is corrected based on ambient temperature. Thus, even when ambient temperature is changed, a key input is detected based on an operation input value obtained by correction, and thus it is possible to improve the usability.

As described above, according to one or more embodiments of the present disclosure, it is possible to achieve a high degree of usability. Note that the advantages described above are not necessarily intended to be restrictive, and any other advantages described herein and other advantages that will be understood from the present disclosure may be achievable, in addition to or as an alternative to the advantages described above.

### BRIEF DESCRIPTION OF THE DRAWINGS

FIG. 1 is a top view illustrating a schematic configuration of an input device according to an embodiment of the present disclosure;

FIG. 2 is a schematic cross-sectional view of the input device shown in FIG. 1;

FIG. 3 is an explanatory diagram illustrated to describe the operation when a key is inputted to the input device according to the exemplary embodiment;

FIG. 4 is an explanatory diagram illustrated to describe a capacitive element in the input device according to the exemplary embodiment;

FIG. 5 is a schematic view illustrating a positional relationship between key arrangement and capacitive elements C1 in the input device;

FIG. 6 is a graph illustrating temperature characteristics of the capacitive element C1 in the input device according to the exemplary embodiment;

FIG. 7 is a graph illustrating temperature characteristics of the capacitive element C1 in the input device according to the exemplary embodiment;

FIG. 8 is a block diagram illustrating an exemplary hardware configuration of an input detection system according to the exemplary embodiment;

FIG. 9 is a functional block diagram illustrating a functional configuration of an input detection system according to the exemplary embodiment;

FIG. 10 is a schematic sectional view illustrating an exemplary configuration of a dummy node used for temperature detection;

FIG. 11 is a graph showing temperature characteristics of a dummy node used for temperature detection;

FIG. 12 is a graph showing temperature characteristics of a dummy node used for temperature detection;

FIG. 13 is a schematic diagram illustrating an exemplary arrangement of a dummy node in the input device;

FIG. 14 is a functional block diagram illustrating an example of the functional configuration of an input detection system according to the modification of detecting temperature using a temperature detection IC;

FIG. 15 is a graph diagram showing the relationship between a load value and a delta value;

FIG. 16 is a graph diagram showing the relationship between the elapsed time during the application of load and a delta value corrected by an ideal correction scale factor;

FIG. 17 is an explanatory diagram illustrated to describe a method of setting a correction scale factor in consideration of reverse correction according to the exemplary embodiment;

FIG. 18 is a diagram showing an example of a delta value correction table according to the exemplary embodiment;

FIG. 19 is a flowchart showing an example of processing steps of an information processing method according to the exemplary embodiment;

FIG. 20 is a graph diagram showing load sensitivity characteristics of a delta value of the input device in the case where temperature compensation is not performed;

FIG. 21 is a graph diagram showing load sensitivity characteristics of a delta value of the input device in the case where temperature compensation according to the exemplary embodiment is performed; and

FIG. 22 is a graph diagram showing load sensitivity characteristics of a delta value of the input device in the case where temperature compensation is performed at an ideal correction scale factor that is set based on a reference condition.

### DETAILED DESCRIPTION OF THE EMBODIMENT(S)

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

The description will be given in the order of following items.

1. Configuration of input device

2. Background leading to embodiment of present disclosure

3. Configuration of input detection system
3-1. Hardware configuration
3-2. Functional configuration

4. Temperature detection process
4-1. Temperature detection process using dummy node
4-2. Temperature detection process using temperature detection IC

5. Correction scale factor decision process
5-1. Decision of reference condition
5-2. Reverse correction
5-3. Setting of delta value correction table
5-4. Process during temperature compensation

6. Information processing method

7. Result of temperature compensation process

8. Supplement

In one preferred embodiment of the present disclosure, an electrostatic capacitive keyboard is used as an input device. The electrostatic capacitive keyboard detects an operation input (that is, an amount of pressing force by an operation object such as fingers) to each of a plurality of key regions provided on a sheet-like operation member based on the capacitance variation amount (delta value which will be described later) of capacitive elements that are arranged in association with the respective key regions. The configuration of an input device according to a preferred embodiment of the present disclosure will be described with reference to item 1 “Configuration of input device” described later. Then, the temperature dependence of capacitance of a capacitive element in an input device according to the exemplary embodiment, which studied by the inventors and the background leading to the embodiments of the present disclosure by the inventors will be described with reference to item 2 “Background leading to embodiment of present disclosure” described later.

Then, the configuration of an input detection system for detecting a key input in the input device according to the exemplary embodiment will be described with reference to item 3 “Configuration of input detection system” described later. In the input detection system according to the exemplary embodiment, a temperature compensation process for correcting an operation input value (for example, amount of variation in capacitance of a capacitive element described above [delta value]) indicating an operation input to a key region is performed based on temperature of the operating environment of the input device. The temperature compensation process includes a process for detecting temperature of the operating environment of the input device (hereinafter referred to as “temperature detection process”), a process for deciding a correction value (correction scale factor) for a delta value that is a detection signal (hereinafter referred to as “correction scale factor decision process”), and a process for correcting a delta value based on a decided correction scale factor (hereinafter referred to as “delta value correction process”). The respective processes in the temperature compensation process corresponding to item 4 “Temperature detection process” and item 5 “Correction scale factor decision process” will be described in detail.

Then, the processing steps in a temperature compensation method according to the exemplary embodiment will be described with reference to item 6 “Information processing method” described later. Then, the result obtained by applying a temperature compensation process according to the exemplary embodiment will finally be described in comparison with the case in which the temperature compensation process is performed with reference to item 7 “Result of temperature compensation process” described later.

In the exemplary embodiment, the presence or absence of a key input is determined by determining an input state for each key using an operation input value obtained by the temperature compensation process. The input state may include a state in which an operation input is determined to be valid (KEY ON state) and a state in which an operation input is determined to be invalid (KEY OFF state). This determination makes it possible to determine a key input that reflects a change in temperature of the operating environment, thereby improving the usability.

### 1. Configuration of Input Device

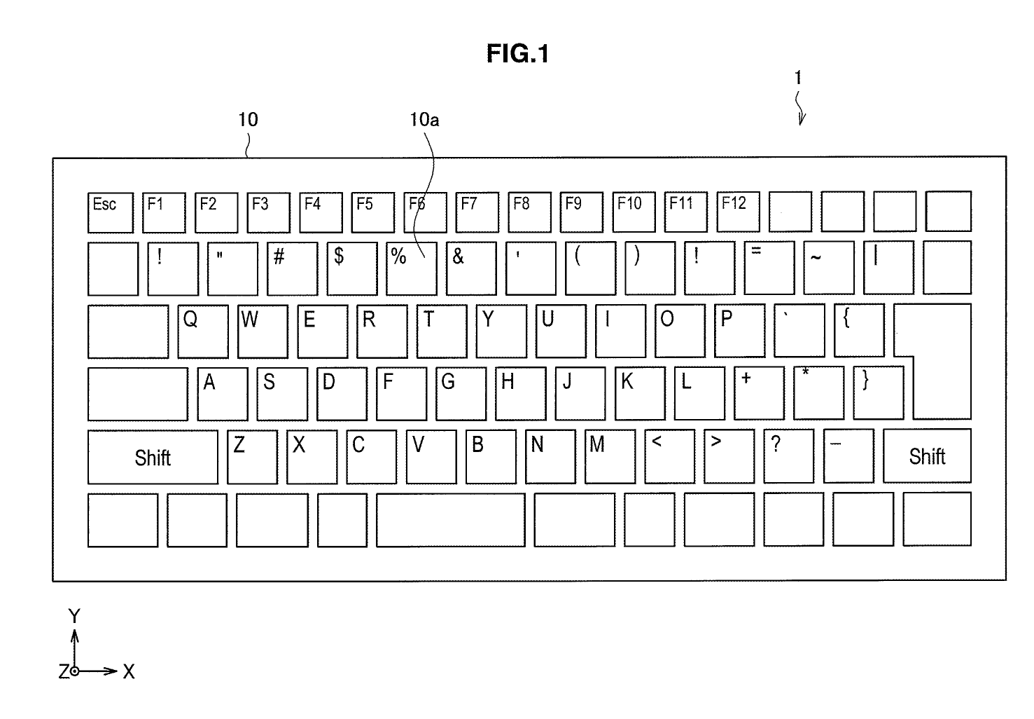

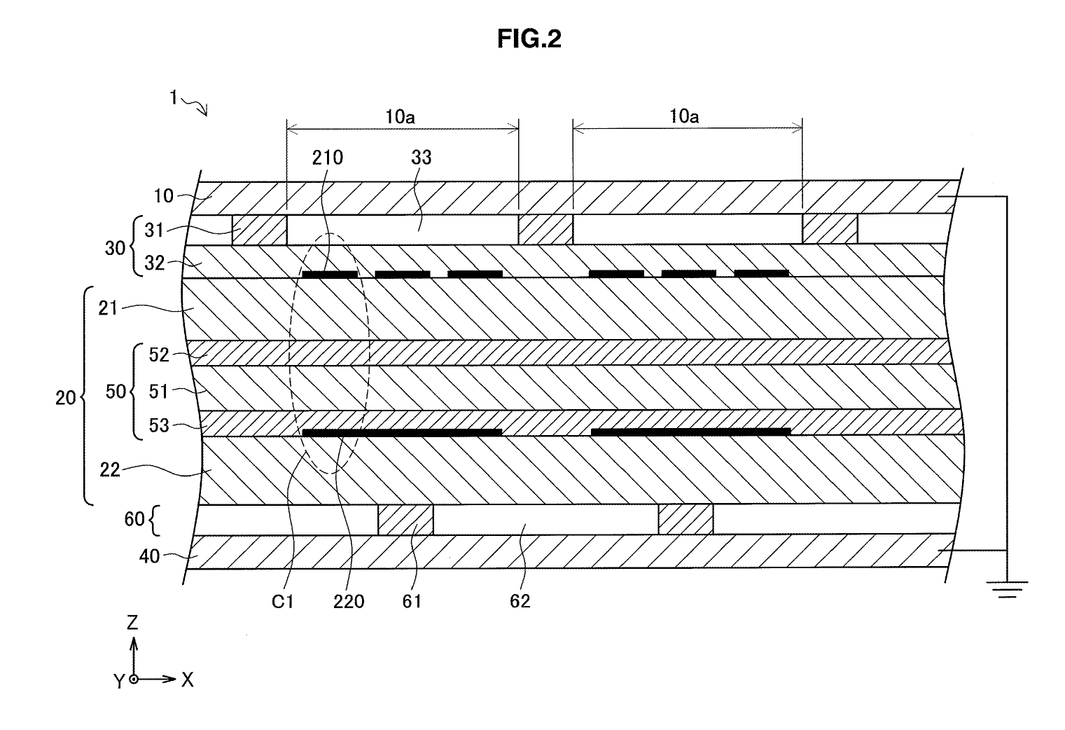

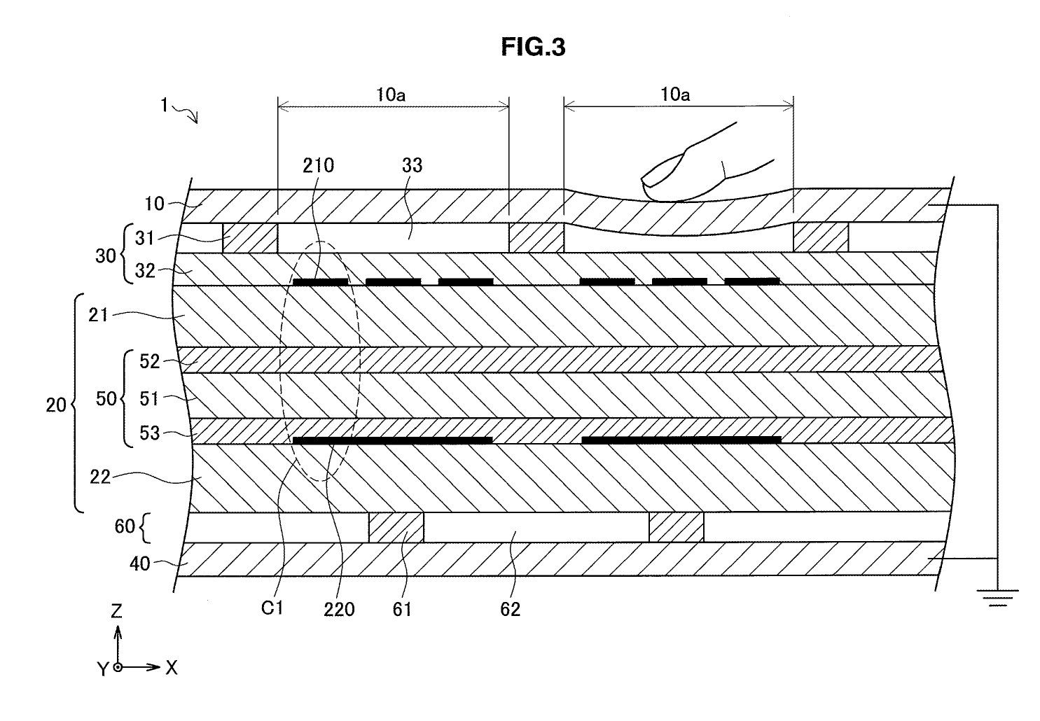

The configuration of an input device according to one preferred embodiment of the present disclosure will be described with reference to FIGS. 1 to 3. FIG. 1 is a top view illustrating a schematic configuration of an input device according to an embodiment of the present disclosure. FIG. 2 is a schematic cross-sectional view of the input device shown in FIG. 1. FIG. 3 is an explanatory diagram illustrated to describe the operation when a key is inputted to the input device according to the exemplary embodiment.

Referring to FIGS. 1 and 2, the input device 1 according to the exemplary embodiment is configured to include a shield layer 40, an electrode board 20, a support 30, and an operation member 10, which are stacked on one another in this order. The input device 1 is used, for example, as a keyboard of a connection device such as PCs. In the following, there will be described a case of the selection of a key with the finger that is an example of an operation object, which can be most commonly used as an operation input to a keyboard. However, the selection of a key may be performed using other parts of the user's body or tools such as a stylus.

In the following description, two directions perpendicular to each other in a plane of the input device 1 are defined as the X-axis direction and Y-axis direction. The direction in which the components in the input device 1 are stacked (depthwise direction) is defined as the Z-axis direction. The positive direction of the Z-axis (direction in which the operation member 10 is disposed) is also referred to as upward or surface direction, and the negative direction of the Z-axis is also referred to as downward or back direction. FIGS. 2 and 3 correspond to cross-sectional views taken along the X-Z plane in the input device 1.

Operation Member

The operation member 10 is a sheet-like member that is disposed on the front surface (upper surface) of the input device 1. The operation member 10 includes a plurality of key regions 10a formed thereon. The key region corresponds to individual keys in the keyboard. The operation member 10 is made of conductive metal materials such as copper (Cu) and aluminum (Al), and is connected to the ground potential. Materials of the operation member 10 are not limited to such examples, and any other conductive materials may be used as a material for the operation member 10.

The operation member 10 has a thickness of, for example, several tens to several hundreds of micrometers. The operation member 10 is configured to be deformable toward the electrode board 20 by the operation input to the key region 10a (that is, the pressing to the key region 10a with the user's finger) as shown in FIG. 3. The thickness of the operation member 10 is not limited to such examples, and may be appropriately set in consideration of the user's feeling when pressing the key region 10a (feeling through a keystroke), the accuracy of key input detection, or other considerations.

The key region 10a corresponds to a key that is pressed (stroked) by the user and the key region 10a has a shape and size depending to the type of keys. The key region 10a may have individual key marks in an appropriate manner. The key marks may indicate a type of keys, a position (contour) of each key, or a combination of two. The key may be marked using a suitable printing method, such as screen, flexographic, and gravure printings. In the following description, when it is intended to represent a case in which an operation input is performed on the key region 10a, the key region 10a is often referred to as simply “key”. For example, the phrase “pressing a key” in the input device 1 as used herein may indicate that the “key region 10a is pressed”.

The operation member 10 may be configured to further include a flexible insulating plastic sheet that is stacked on the conductive layer made of conductive materials described above. An example of the flexible insulting plastic sheet includes PET (polyethylene terephthalate), PEN (polyethylene naphthalate), PMMA (polymethyl methacrylate), PC (polycarbonate), and PI (polyimide). In this case, the key mark corresponding to each key is printed on the surface of the plastic sheet. When the plastic sheet is stacked on the conductive layer, the conductive layer and the plastic sheet may include a composite sheet obtained by previously bonding a film of the conductive layer to a surface of a resin sheet. The operation member 10 may be configured by forming the conductive layer formed on the surface of the plastic sheet by vapor deposition or sputtering, or it may be configured by printing a coating film, such as conductive paste, on the surface of the plastic sheet.

Shield Layer

The shield layer 40 is a sheet-like member that is disposed on the back surface of the input device 1. In the input device 1, the electrode board 20, the first support 30, and the second support 60 are held between the shield layer 40 and the operation member 10. The shield layer 40 is made of conductive metal materials such as copper and aluminum, and is connected to the ground potential, which is similar to the operation member 10. Materials of the shield layer 40 are not limited to such examples, and any other conductive materials may be used as a material for the shield layer 40. The shield layer 40 is used to shield electromagnetic noise coming from the outside of the input device 1. The shield layer 40 has a thickness of, but not particularly limited to, several tens to several hundreds of micrometers. The shield layer 40 may be configured to further include an insulating plastic sheet stacked thereon.

First Support and Second Support

The first support 30 is disposed between the operation member 10 and the electrode board 20. The first support 30 is configured to include a plurality of structures 31 and a substrate 32 so that the structures 31 are formed on the substrate 32.

The substrate 32 is formed of an insulating plastic sheet that is made of PET, PEN, PC and other polymer films. The substrate 32 is stacked on the electrode board 20. The substrate 32 has a thickness of, but not particularly limited to, several micrometers to several hundreds of micrometers.

The structures 31 have the same height (for example, several micrometers to several hundreds of micrometers). The structures 31 are formed on the substrate 32 to divide the key regions 10a of the operation member 10 into their particular parts. The structures 31 allow the substrate 32 to be connected to the operation member 10. The region in which the structures 31 are not formed (that is, a region corresponding to the key region 10a) defines a void space 33. With such arrangement configuration, the operation input to the key region 10a changes the distance between the operation member 10 and the electrode board 20 in at least a portion corresponding to the key region 10a being pressed (see FIG. 3).

The structures 31 are made of a material having relatively high rigidity in view of the achievement of high degree of usability (click feeling or stroke feeling) and the improvement of detection accuracy in the key region 10a, but the structures 31 may be made of a resilient material. The structures 31 are made of an electrically insulating resin material such as ultraviolet curable resin and are formed on the surface of the substrate 32 using an appropriate technique including the transfer process.

The second support 60 is disposed between the shield layer 40 and the electrode board 20. The second support 60 includes a plurality of structures 61. The structures 61 have the same height (for example, several micrometers to several hundreds of micrometers). The structures 31 may be formed at a position (for example, substantially central portion of each key region 10a) shifted by a half pitch from the structures 31 of the first support 30. The structures 61 allow the shield layer 40 to be connected to the electrode board 20. The region in which the structures 61 are not formed defines a space 62. In this way, the input device 1 according to the exemplary embodiment includes spaces 33 and 62 that are formed in the front surface and back surface, respectively, and are deformable when they are pressed by the finger. The structures 61 may have similar material and shape to the structures 31 of the first support 30.

Electrode Board

The electrode board 20 has a layered structure in which a first wiring board 21 is stacked on a second wiring board 22 via the bonding layer 50. The first wiring board 21 has an electrode wire 210 (pulse electrode) that extends in the Y-axis direction on the surface thereof. The second wiring board 22 has an electrode wire 220 (sensing electrode) that extends in the X-axis direction on the surface thereof.

The first and second wiring boards 21 and 22 are formed of a plastic sheet made of an insulating material. For example, the first and second wiring boards 21 and 22 are formed of a plastic sheet, a glass substrate, or a glass epoxy substrate, which is made of PET, PEN, PC, PMMA or like material. The first and second wiring boards 21 and 22 have a thickness of, but not particularly limited to, several tens to several hundreds of micrometers.

The first and second electrode wires 210 and 220 are formed on the first and second wiring boards 21 and 22, respectively, by etching techniques using Al, Cu, or any other conductive metals, the printing of a metal paste such as silver (Ag), or any other forming method.

The bonding layer 50 is configured to include a bonding board 51 and adhesive layers 52 and 53 stacked on both sides of the bonding board 51. The bonding board 51 is made of an insulating material, and similarly, the adhesive layers 52 and 53 are made of an insulating material. The bonding board 51 may be formed of a plastic sheet, a glass substrate, or a glass epoxy substrate, which is made of PET, PEN, PC, PMMA or like material. The adhesive layers 52 and 53 may be formed of various kinds of materials that are used as optical clear adhesive (OCA).

The first and second wiring boards 21 and 22 are stacked via the bonding layer 50 so that the first and second electrode wires 210 and 220 face to each other. The first and second electrode wires 210 and 220 face to each other with a layer of insulator material (i.e. the first wiring board 21 and the bonding layer 50) interposed therebetween, and thus a capacitive element is formed in an intersection region between the electrode wires 210 and 220 (hereinafter, this region is also referred to as “node”). The electrode wires 210 and 220 are substantially perpendicular to each other in their extending directions, and thus a plurality of nodes may be formed in the crossing of a single electrode wire 210 and a plurality of electrode wires 220.

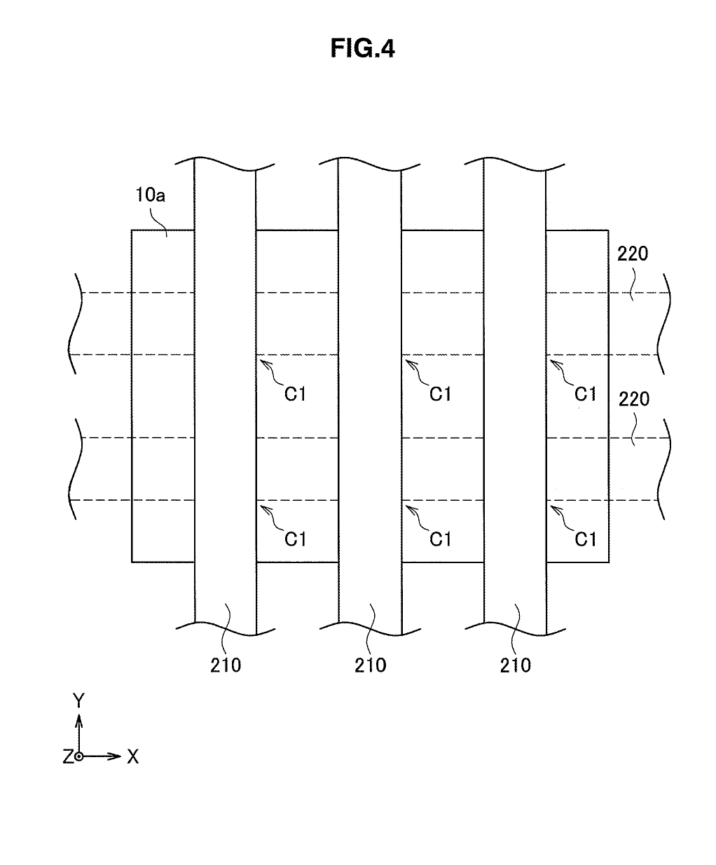

FIG. 4 schematically illustrates how a capacitive element is formed by an overlap between the electrode wires 210 and 220. FIG. 4 is an explanatory diagram illustrated to describe a capacitive element in the input device 1 according to the exemplary embodiment. FIG. 4 schematically illustrates a cross-sectional view taken along a plane corresponding to the surface of the electrode board 20 in a key region 10a.

As shown in FIG. 4, a capacitive element C1 is formed at an overlap portion between the electrode wire 220 that extends in the X-axis direction and the electrode wire 210 that extends in the Y-axis direction. In the exemplary embodiment, the electrode wires 210 and 220 are formed so that at least one capacitive element C1 may be formed in a key region 10a.

Referring to FIG. 3, a description will be given of how to detect a key input to the input device 1 according to the exemplary embodiment. As shown in FIG. 3, when a key operation input is performed, a key region 10a corresponding to the key is pressed by the finger in the Z-axis direction. When the key region 10a is pressed, the distance between the operation member 10 (specifically, the conductive layer thereof) and the capacitive element C1 varies, and thus capacitance of the capacitive element C1 varies. The capacitance variation amount of the capacitive element C1 (hereinafter, also referred to as “delta value”) represents the amount of change in the distance between the key region 10a and the capacitive element C1 depending on an operation input to the key region 10a.

In the exemplary embodiment, the input of a key corresponding to a target node is detected based on a delta value detected at each node. For example, a delta value or a value calculated from the delta value (for example, a differential delta value representing a time derivative of a delta value, or a normalized delta value obtained by normalizing a delta value) is compared with a predetermined threshold, and thus the input of a key corresponding to the node may be detected. These delta value, differential delta value, and/or normalized delta value, or statistics thereof may be a value representing an operation input to a key, and thus these values may be sometimes collectively referred to as “operation input value”. The detection of a key input based on a delta value will be described in detail with reference to item 3 “Configuration of input detection system” described later.

In this way, in the exemplary embodiment, the key input is detected based on the capacitance variation amount of the capacitive element C1, and thus the capacitance of the capacitive element C1 (which will be referred to as initial capacitance or Base Signal value) in the absence of an operation input is adjusted to a predetermined value. Accordingly, the shape of the electrode wires 210 and 220 (specifically, shape of a portion [electrode portion] that may be an electrode of the capacitive element C1), and the thickness and material of the insulator located between the electrode wires 210 and 220 are set appropriately so that the Base Signal value of the capacitive element C1 may be a predetermined value.

In the following, the description will be given on the assumption that a delta value is a positive value, for convenience of description and better understanding of comparison between a delta value and a threshold. As described above, a delta value is a variation in capacitance of the capacitive element C1. Thus, a delta value may be calculated by subtracting the capacitance of the capacitive element C1 (i.e. Base Signal value) in the absence of an operation input (a state shown in FIG. 2) from the capacitance of the capacitive element C1 in the presence of an operation input (a state shown in FIG. 3). On the other hand, in the state shown in FIG. 3, as the distance between the key region 10a and the capacitive element C1 becomes smaller, the capacitance of the capacitive element C1 becomes smaller than the state shown in FIG. 2. In this way, a delta value obtained only from the difference between capacitance values can be a negative value. Meanwhile, in the exemplary embodiment, a delta value is set to be a positive value by appropriately changing a sign thereof. Even when a delta value is set to be a negative value, an inversion of the sign of a value, such as a threshold, to be compared with a delta value makes it possible to perform a similar process to a detection process of a key input, which will be described below.

In the example shown in FIG. 4, there are provided six capacitive elements C1 in one key region 10a (that is, there are six nodes), but the exemplary embodiment is not limited to this example. Any number of nodes may be provided in one key region 10a. As described above, in the exemplary embodiment, detection of a key input is performed based on the capacitance variation amount of the capacitive element C1. Thus, a plurality of capacitive elements C1 are disposed in one key region 10a, and statistics such as the sum or average value of the capacitance variation amounts of these capacitive elements C1 are used, thereby improving the accuracy of key input detection. In the exemplary embodiment, the number of nodes provided in one key region 10a may be set appropriately in view of the type or arrangement of keys. For example, for a key having higher input frequency or a key that is likely to have low detection accuracy because of the position to be arranged (for example, a key located at nearly the end of the plane as compared with other keys), more nodes are provided, and thus the accuracy of key input detection can be improved.

In the example shown in FIG. 4, for simplicity purposes, the electrode wires 210 and 220 are substantially linear in shape, and a portion corresponding to an electrode constituting the capacitive element C1 is substantially rectangular in shape, but the exemplary embodiment is not limited to this example. For example, the electrode wires 210 and 220 may include an electrode portion having a predetermined area and shape, such as annular shape or a diamond shape, in a region to be provided with the capacitive element C1. The electrode portions may be connected in series in the X-axis or Y-axis direction. The shape of the electrode wires 210 and 220 is appropriately set and the shape of the electrode portion is adjusted, and thus the accuracy of delta value detection can be improved.

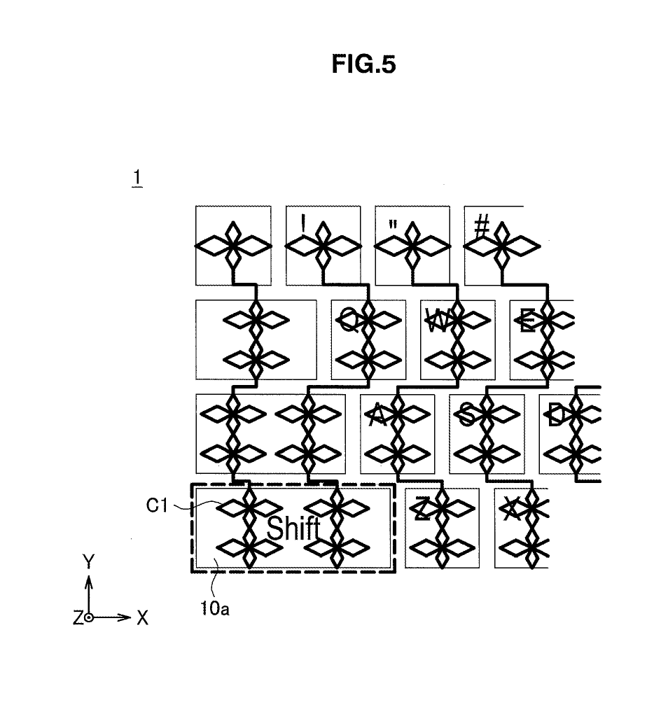

FIG. 5 illustrates a positional relationship between the key arrangement and the capacitive element C1 in the input device 1. FIG. 5 is a schematic view illustrating a positional relationship between the key arrangement and the capacitive element C1 in the input device 1. In FIG. 5, the capacitive elements C1 are overlapped on each other, as shown in a portion of the top view of the input device 1.

In the example shown in FIG. 5, the capacitive element C1 includes an electrode portion having a radially expanded wiring shape, which is not a simple shape as illustrated in FIG. 4. For example, four capacitive elements C1 are provided in the key region 10a that is encircled by broken lines in the figure. In other words, the key region 10a encircled by broken lines includes four nodes, and thus four delta values corresponding to the respective nodes are detected from the key region.

The configuration of the input device 1 according to the exemplary embodiment has been described roughly. As described above, the input device 1 is configured to include the shield layer 40, the second support 60, the electrode board 20, the first support 30, and the operation member 10, which are stacked on one another. The detection of a key input may be performed using the capacitance variation amount of the capacitive element C1 that includes two layers of wiring boards formed in the electrode board 20. In this way, the input device 1 can detect a key input with a relatively simple structure. Thus, thinning and weight reduction of the input device 1 can be achieved.

The keyboards having an electrostatic capacitive touch panel are typically provided with capacitive elements arranged to be uniformly distributed in the plane of the touch panel, as well known in the art. Thus, the arrangement of keys is not necessarily corresponded to the arrangement of capacitive elements. On the other hand, in the input device 1, the shape of the electrode wires 210 and 220 can be set appropriately, and the number and arrangement of capacitive elements can be adjusted depending on the arrangement of keys. In this way, the input device 1 can set the optimal key arrangement configuration and signal processing for enhancing the key input detection accuracy for each key. In addition, in the input device 1, only the necessary number of capacitive elements may be formed, thereby reducing the number of electrodes, as compared with the keyboards having a touch panel provided with capacitive elements arranged to be uniformly distributed in the plane of the touch panel as well known in the art. As a result, it is possible to reduce the load imposed on the signal processing when a key input is detected, and thus it is possible to use a more inexpensive processor (controller IC 110 or main MCU 120 described later) to perform the signal processing.

For the input device 1 according to the exemplary embodiment, for example, it is possible to refer to WO13/132736 filed by the same applicant as the present application.

### 2. Background Leading to Embodiment of Present Disclosure

There will be described the results obtained by the inventors who have studied temperature dependence of capacitance of the capacitive element C1 in the input device 1 according to the exemplary embodiment, and the background that leads to the embodiment of the present disclosure by the inventors will be described. The inventors have conducted the experiment to investigate temperature characteristics for the capacitive element C1 in the input device 1 as described above.

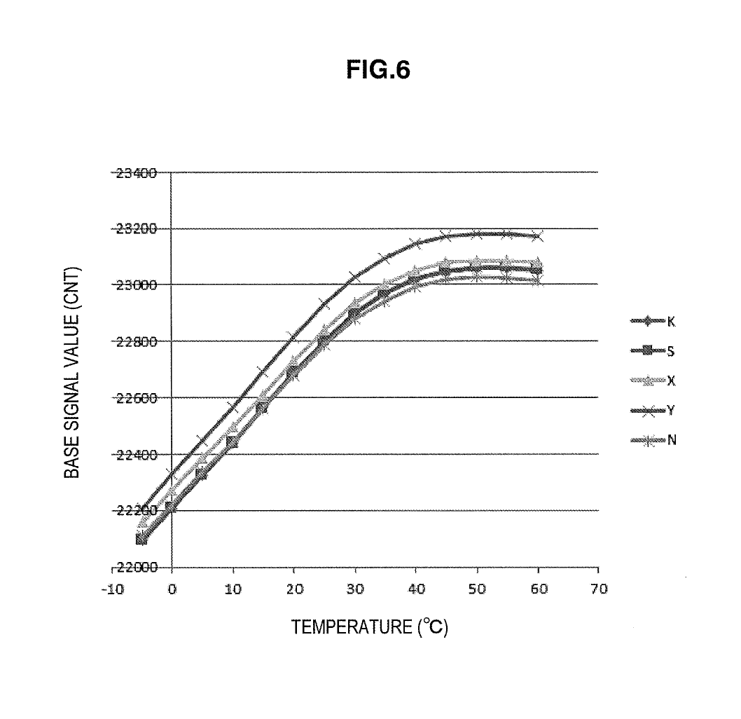

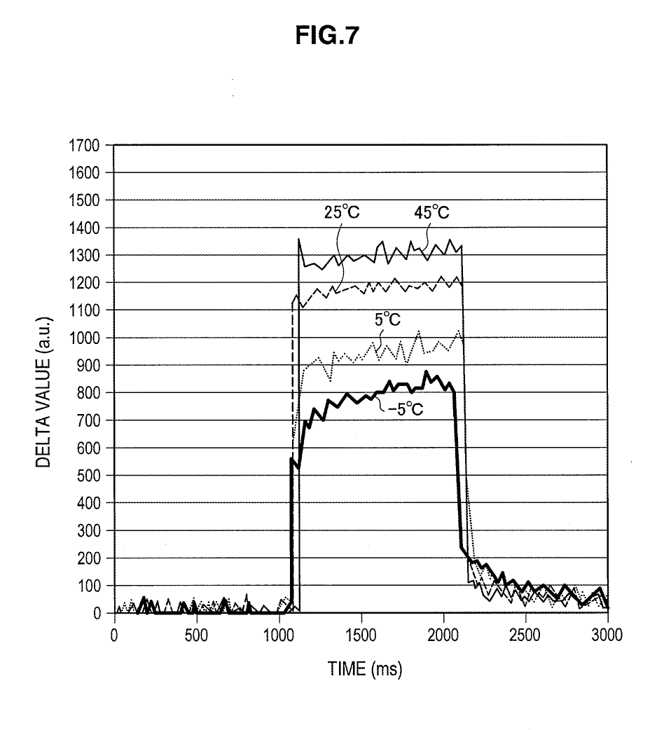

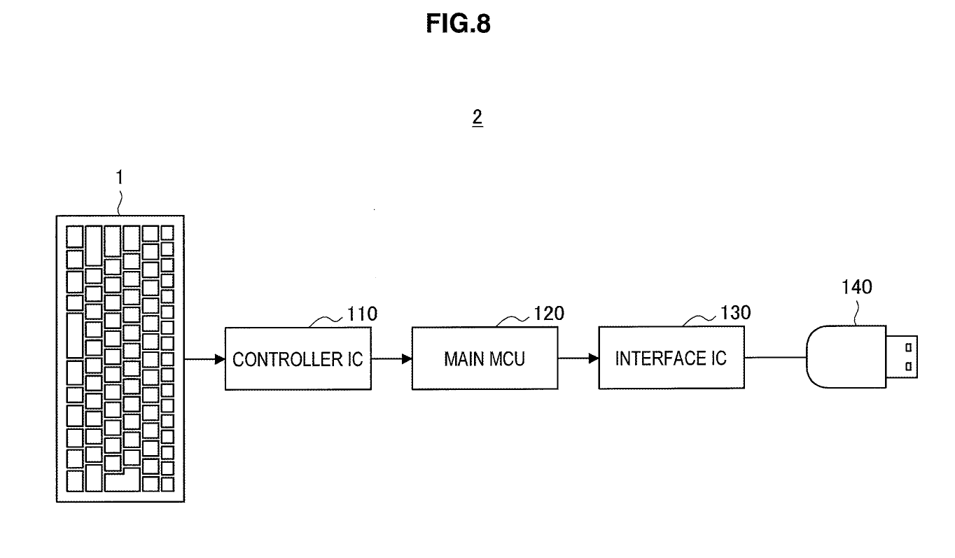

FIGS. 6 and 7 show the experimental results. FIGS. 6 and 7 are graphs showing temperature characteristics for the capacitive element C1 in the input device 1 according to the exemplary embodiment. In FIG. 6, the horizontal axis represents temperature of the operating environment of the input device 1, the vertical axis represents a base signal value at a node corresponding to a key region 10a in the input device 1, and the relationship between the two is plotted. FIG. 6 shows the results obtained for the keys of “K”, “S”, “X”, “Y”, and “N”, as an example. In the graphs of FIG. 6 and the subsequent figures, the unit “CNT” used in the horizontal and vertical axes corresponds to a value obtained by converting a value relating to capacitance of the capacitive element C1, such as delta value or base signal value, into a count value (CNT) in a controller IC 110, which will be described later with reference to FIG. 8. For example, in the exemplary embodiment, the capacitance (for example, a base signal value) of the capacitive element C1 is converted into a count value (CNT) according to the following Equation (1).

Base Signal (CNT)=α×C(pF)+β (1)

In Equation (1), a represents a coefficient determined by performance of the controller IC 110 or the power supply voltage, and β is a constant that is set as a virtual count value when the capacitance of the capacitive element C1 is 0 pF. Equation (1) is an example when the capacitance of the capacitive element C1 is converted into a value to be processed by a processor, and the capacitance of the capacitive element C1 may be processed by converting it appropriately depending on performance or the like of the processor.

In FIG. 7, the horizontal axis represents time, the vertical axis represents a delta value detected at a node corresponding to a key region 10a in the input device 1, and the relationship between the two is plotted. FIG. 7 shows the results obtained for the key of “J”, as an example. In FIG. 7, an operation input to the key region 10a is assumed to be performed by the finger, the key region 10a is started to be pressed under a predetermined load (for example, 50 gF) using a finger-like tool at predetermined first time, then an operation of releasing the tool from the key region 10a is performed at predetermined second time, and during this operation, temporal variations in a delta value at a node corresponding to the pressed key region 10a are illustrated. The first time corresponds to a time at which a delta value in each graph increases sharply, and the second time corresponds to a time at which a delta value in each graph decreases sharply. In the graphs of FIG. 7 and the subsequent figures, the delta value is sometimes illustrated as an arbitrary unit (a.u.) that is normalized using a predetermined reference value.

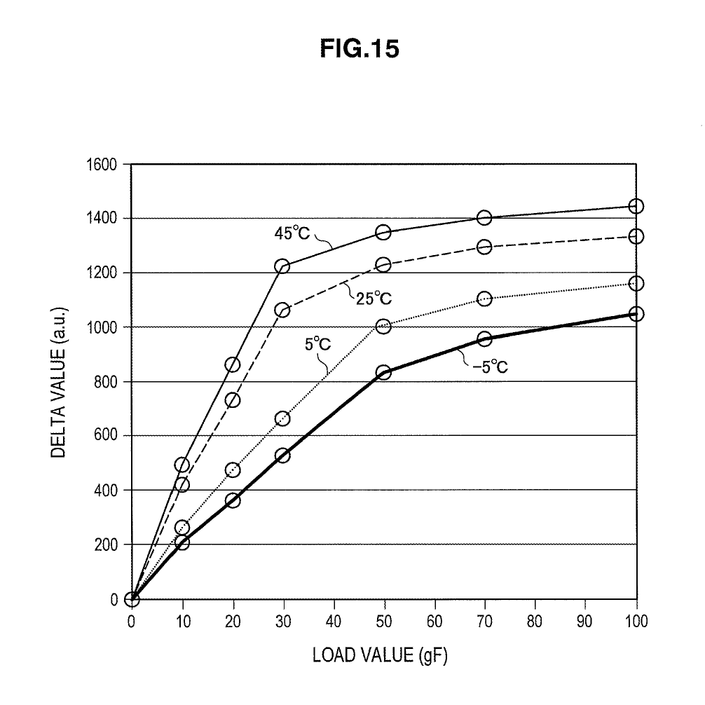

In the graphs of FIGS. 6 and 7 and the subsequent FIGS. 15, 16, 20, 21, and 22, a delta value and a base signal value at one node disposed at a predetermined position in a given key (for example, key of “J”) in the input device 1 out of delta values and base signal values at a plurality of nodes included in the key is plotted as a representative value of the delta value and base signal value for the key.

Referring to FIG. 6, it is found that, in the input device 1, a base signal value of the capacitive element C1 decreases as the temperature decreases. In the example shown in FIG. 6, for example, when the temperature decreases from 25 degrees (25° C.) that is ordinary temperature to minus five degrees (−5° C.), the base signal value decreases by approximately 10%. With the decrease of base signal value, it is assumed that the delta value that is defined as a difference between the capacitance of the capacitive element C1 at the time of pressing the key region 10a and the base signal value is reduced accordingly.

On the other hand, referring to FIG. 7, it is found that, in the input device 1, with the decrease of temperature, even when the key region 10a is pressed under the same load, the detected delta value decreases. In the example shown in FIG. 7, when the temperature decreases from 25 degrees (25° C.) that is ordinary temperature to minus five degrees (−5° C.), the delta value decreases by approximately 33%. As shown in FIG. 7, it was observed that the delta value increases sharply immediately after the key is pressed (at the first time) at high temperatures (for example, 25° C. to 45° C.) and the delta values are substantially fixed in the middle of pressing the key (during a period from the first time to the second time), meanwhile the delta value increases gradually in the middle of pressing the key (during a period from the first time to the second time) at low temperatures (for example, 5° C. to −5° C.).

It is found that, in the input device 1, when the key input state is determined by comparing a delta value with a predetermined threshold, the detectability of the key input may vary depending on a change in the temperature of the operating environment from the results shown in FIGS. 6 and 7. For example, when the key input state is determined by using a threshold adjusted by assuming that it is used at ordinary temperature (25° C.), the key input is difficult to be detected at low temperatures and the key input is easy to be detected at high temperatures. Thus, in the input device 1, the feeling of keystroke may vary depending on the temperature of the operating environment.

The inventors considered the cause for the occurrence of temperature dependence of the delta value in the input device 1. The change in the base signal value of the capacitive element C1 as shown in FIG. 6 is believed to be occurred by the change in the dielectric property of the insulating film layer (first wiring board 21 or bonding board 51 shown in FIG. 2) disposed between the electrode wire 210 and the electrode wire 220 in the capacitive element C1 depending on the temperature. The temperature characteristics of the delta value due to the temperature characteristics of electrical parameters of the capacitive element C1 as described above is hereinafter referred to as “temperature characteristics of delta value due to electrical factors” for the sake of convenience.

On the other hand, as shown in FIG. 3, in the input device 1 according to the exemplary embodiment, the amount of pressing force to the key region 10a by the finger may be detected as a capacitance variation of the capacitive element C1. Thus, it is considered that the temperature characteristics of the delta value are also affected by a change in resilience characteristics of the respective members constituting the input device 1 depending on the temperature. The inventors analyzed this, and then it was found that the adhesive layers 52 and 53 used in the bonding layer 50 have a tendency to increase their hardness (that is, low elastic modulus) as the temperature decreases. The temperature characteristics of the delta value due to the temperature characteristics of structural parameters of the capacitive element C1 are hereinafter referred to as “temperature characteristics of delta value due to structural factors” for the sake of convenience. The results of FIG. 7 show the temperature characteristics of delta value due to electrical factors and the temperature characteristics of delta value due to structural factors together.

In this way, the temperature characteristics of a delta value in the input device 1 can be complicated ones in which electrical factors and structural factors are combined. The technique disclosed in JP 2009-020006A obtains the temperature characteristics of the impedance of the electrostatic capacitance sensor in advance and corrects electrostatic capacitance of an electrostatic capacitance sensor by using the obtained temperature characteristics in the electrostatic type touch panel. However, according to the technique disclosed in JP 2009-020006A, only a method for correcting a change in electrostatic capacitance due to thermal expansion the elastomer (dielectric film) provided between electrodes of electrostatic capacitance sensor is considered. The temperature characteristics due to structural factors as described above are occurred by the configuration of the input device 1 according to the exemplary embodiment, which detects the amount of pressing force on the key region 10a. Thus, even when the technique disclosed in JP 2009-020006A is applied to the input detection system using the input device 1 without any modification, the detection of key input is likely not to be performed with high accuracy.

When a touch panel is used as a keyboard like the input device 1 according to the exemplary embodiment, simple correction of a delta value depending on the temperature is not sufficient to obtain desired results. Thus, it is necessary to perform the correction of a delta value by considering even the usability for a keyboard. For example, when the sensitivity of detection of key input is excessively high as a result of the correction, even a slight contact with the key region 10a by the finger will be detected, which may lead to deterioration of the usability. In the technique disclosed in JP 2009-020006A, temperature compensation in consideration of the usability as described above was not mentioned.

As described above, it was necessary to perform the temperature compensation of a delta value by considering even the usability in the input device 1. The inventors of the present disclosure have studied the temperature compensation in the input device 1 from the viewpoints described above, and then the embodiment described later has been developed. The input detection system according to the exemplary embodiment, in particular, a temperature compensation process to be performed in the input detection system will be described in detail. In the following description, as an example, the case in which the temperature compensation is performed on a delta value detected at a node of the input device 1 will be described. The exemplary embodiment is not limited to such example, and the temperature compensation may be performed on any operation input value that includes a delta value. For example, after the conversion of a delta value into other operation input values (for example, differential delta value or normalized delta value), the correction of other operation input values depending on the temperature may be performed. The temperature compensation is only necessary to be performed on an operation input value used in determining the input state until a process for determining the key input state is performed, and thus a similar effect can be achieved as long as the temperature compensation is performed at any stage until an operation input value to be used for determination is obtained (calculated). The “delta value” that is a target to be subjected to the temperature compensation in the following description may be interchangeable appropriately with other operation input values.

### 3. Configuration of Input Detection System

The configuration of the input detection system according to the exemplary embodiment will be described. In the input detection system according to the exemplary embodiment, the temperature compensation process is performed on a delta value detected at each node of the input device 1 depending on the temperature of the operating environment. A key corresponding to the node in which the delta value is detected is specified, and a determination process of the input state for the specified key is performed based on the delta value that is subjected to the temperature compensation. Information associated with the key is inputted to a connection device connected to the input device 1, based on the result obtained by the determination of the input state for the key.

3-1. Hardware Configuration

The hardware configuration of the input detection system according to the exemplary embodiment will be described with reference to FIG. 8. FIG. 8 is a block diagram illustrating an example of the hardware configuration of the input detection system according to the exemplary embodiment.

Referring to FIG. 8, the input detection system 2 according to the exemplary embodiment is configured to include the input device 1, a controller integrated circuit (IC) 110, a main microcontroller (MCU) 110, an interface IC 130, and a connector 140. The configuration of the input device 1 is described in the above item 1 “Configuration of Input Device”, and thus detailed description thereof is omitted.

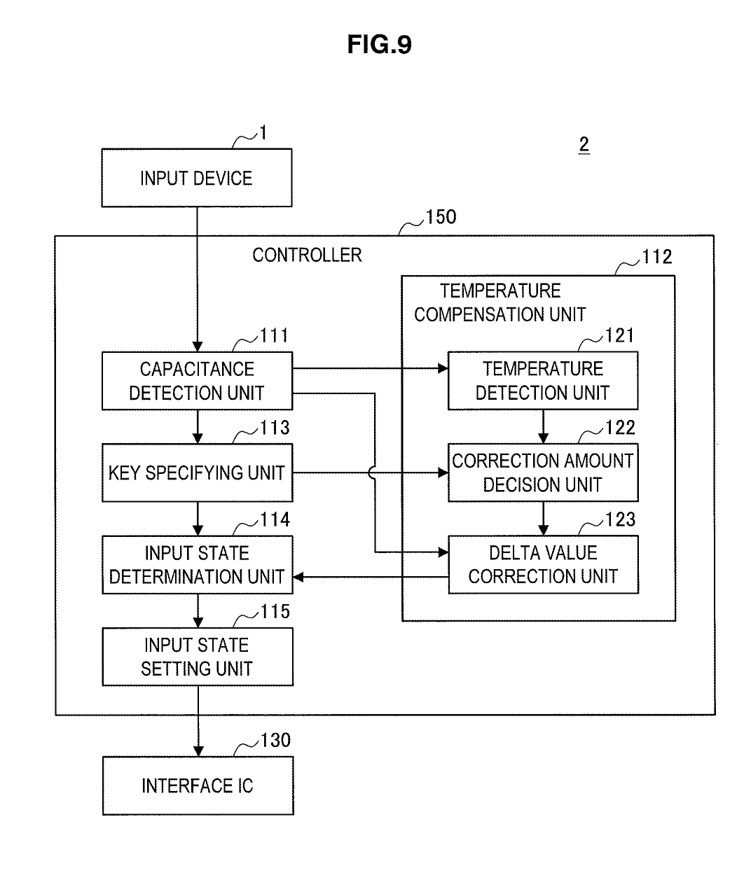

The controller IC 110 is a processor having a function of detecting the capacitance for each node in the input device 1. A base signal value is detected from a node on which an operation input is not performed. On the other hand, a capacitance value corresponding to the operation input is detected from a node on which an operation input is performed. The controller IC 110 can detect a delta value at each node based on the capacitance value detected at the node on which an operation input is performed and the base signal value at the node. A process to be performed by the controller IC 110 corresponds to the process performed by a capacitance detection unit 111 shown in FIG. 9, which will be described later.

The node is formed in the intersection region between a plurality of electrode wires 220 that extend in the X-axis direction and a plurality of electrode wires 210 that extend in the Y-axis direction, and thus the node may be represented by addresses of X and Y. The controller IC 110 can detect a delta value at each node in association with the address of a target node. The controller IC 110 associates information regarding a delta value detected at each node with information regarding an address of a target node (address information) and transmits the associated information to the main MCU 120 in a subsequent stage. As described later, in the exemplary embodiment, a dummy node for detection of temperature may be provided in the input device 1, and the temperature may be detected based on the base signal value at the dummy node. When the temperature is detected based on the base signal value at a dummy node, the controller IC 110 transmits information regarding the base signal value at the dummy node to the main MCU 120 in the subsequent stage. The processing in the controller IC 110 may be performed by allowing the controller IC 110 (that is, processor) to be executed in accordance with a predetermined program.

The main MCU 120 compensates the temperature compensation of a delta value detected at each node, and performs a process for determining a key input based on the temperature compensated delta value. The process to be performed by the main MCU 120 includes a process for correcting a detected delta value depending on the temperature of the operating environment (hereinafter also referred to as “temperature compensation process”), a process for specifying a key from which a delta value is detected (hereinafter also referred to as “key specifying process”), a process for determining an input state of a key based on a temperature compensated delta value (hereinafter also referred to as “input state determination process”), and a process for setting an input state for each key based on a determined input state (hereinafter also referred to as “input state setting process”). The processes to be performed by the main MCU 120 are corresponded to the processes to be performed by a temperature compensation unit 112, a key specifying unit 113, an input state determination unit 114, and an input state setting unit 115, which are shown in FIG. 9 described later. The temperature compensation process, the key specifying process, the input state determination process, and the input state setting process will be described in detail with reference to FIG. 9 in item 3-2 “Functional configuration” described later. The process performed by the main MCU 120 may be executable by allowing a processor provided in the main MCU 120 to be executed in accordance with a predetermined program.

The main MCU 120 can determine the input state of each key in the state in which temperature compensation is performed by sequentially performing the temperature compensation process, the key specifying process, the input state determination process, and the input state setting process on each node included in the input device 1. The input state of a key may include a KEY ON state (simply also referred to as “ON state”) and a KEY OFF state (simply also referred to as “OFF state”). The KEY ON state indicates a state in which an operation input for a key is determined to be valid. On the other hand, the KEY OFF state indicates a state in which an operation input for a key is determined to be invalid.

The main MCU 120 transmits information that indicates the content associated with a key determined to be in the KEY ON state to the interface IC 130 in a subsequent stage. In this way, in the KEY ON state, information associated with a key may be transmitted. However, the main MCU 120 may transmit the results obtained by performing the input state determination process of all the keys to the interface IC 130 in the subsequent stage, and then only information associated with a key determined to be in the KEY ON state may be extracted from among the transmitted results by any configuration succeeding to the interface IC 130.

The interface IC 130 is a processor that serves as an interface between the input device 1 and a connection device connected to the input device 1. For example, the interface IC 130 is connected to the connector 140 that is used to connect the input device 1 to a connection device. The interface IC 130 performs a signal conversion in a way suitable for the type of the connector 140 depending on the type of the connector 140 and transmits information associated with a key determined to be in the KEY ON state to a connection device. For example, the connection device allows a display unit to display characters or symbols corresponding to the key. The process performed by the interface IC 130 may be appropriately set depending on the type of the connector 140. The connector 140 may be universal serial bus (USB) connectors.

The hardware configuration of the input detection system 2 according to the exemplary embodiment has been described with reference to FIG. 8. The functional configuration corresponding to the input detection system 2 shown in FIG. 8 will be described.

3-2. Functional Configuration

The functional configuration of the input detection system 2 according to the exemplary embodiment will be described with reference to FIG. 9. FIG. 9 is a functional block diagram illustrating an example of the functional configuration of the input detection system 2 according to the exemplary embodiment. The functional configuration shown in FIG. 9 corresponds to the hardware configuration of the input detection system 2 shown in FIG. 8. In the exemplary embodiment, any type of device known in the art, which is typically used to connect a keyboard to the information processing device, may be used as the interface IC 130 and the connector 140. Thus, FIG. 9 mainly illustrates the function performed by the controller IC 110 and the main MCU 120 among the components shown in FIG. 8.

Referring to FIG. 9, the input detection system 2 according to the exemplary embodiment is configured to include a capacitance detection unit 111, a temperature compensation 112, a key specifying unit 113, an input state determination unit 114, and an input state setting unit 115, as functional blocks. FIG. 9 illustrates functions performed in a controller 150 (corresponding to the information processing device according to the exemplary embodiment) for simplicity purposes, but in practical, the controller 150 may be configured as a processor corresponding to the controller IC 110 and the main MCU 120. In other words, the functions performed by the controller 150 in FIG. 9 may be implemented by enabling the processor corresponding to the controller IC 110 and the main MCU 120 to execute in accordance with a predetermined program. For example, the function corresponding to the capacitance detection unit 111 is executed by the controller IC 110, and other functions (temperature compensation unit 112, key specifying unit 113, input state determination unit 114, and input state setting unit 115) may be executed by the processor provided in the main MCU 120. The exemplary embodiment is not limited to this example. The functions shown in FIG. 9 may be executed by any processor of the controller IC 110 and the main MCU 120, or may be executed by other processing circuitry (information processing device) which is not shown in the figure.

The capacitance detection unit 111 detects capacitance at each node of the input device 1. For example, the capacitance detection unit 111 detects capacitance at each node at a predetermined sampling rate in a sequential manner. A base signal value is detected from a node at which an operation input is not performed, and a capacitance value corresponding to the amount of pressing force applied to the key region 10a by the operation input is detected from a node at which an operation input is performed. The capacitance detection unit 111 can detect a delta value at each node based on the capacitance value detected at the node on which the operation input is performed and the base signal value at the node. The capacitance detection unit 111 detects a delta value at each node in association with an address of the node. The capacitance detection unit 111 supplies information regarding the detected delta value to a delta value correction unit 123 of the temperature compensation unit 112, which will be described later. The capacitance detection unit 111 supplies address information of a node corresponding to the detected delta value to the key specifying unit 113. When the temperature is detected based on the base signal value at a dummy node that is provided in the input device 1, the capacitance detection unit 111 supplies information regarding the base signal value at the dummy node to a temperature detection unit 121 of the temperature compensation unit 112, which will be described later.

The key specifying unit 113 specifies a key corresponding to a node at which a delta value is detected, based on the node address information. The process performed by the key specifying unit 113 corresponds to the key specifying process described above. For example, in the input detection system 2 according to the exemplary embodiment, a storage device (not shown) capable of storing various types of information may be provided, and a positional relationship between an address of a node and key arrangement in the input device 1 is stored in a storage device. The key specifying unit 113 refers to the storage device and can specify a key corresponding to the node at which a delta value is detected, based on the positional relationship between an address of the node and key arrangement. The storage device may be a memory provided in the main MCU 120 or may be provided as a separate configuration from the main MCU 120. The storage device is not particularly limited, and examples thereof include a magnetic storage device such as hard disk drive (HDD), a semiconductor storage device, an optical storage device, and a magneto-optical storage device. The key specifying unit 113 supplies information regarding the specified key to the input state determination unit 114 and a correction amount decision unit 122 of the temperature compensation unit 112 described below.

The temperature compensation unit 112 corrects a detected delta value based on the temperature (ambient temperature) of the operating environment of the input device 1. The process performed by the temperature compensation unit 112 corresponds to the temperature compensation process described above. Specifically, the function of the temperature compensation unit 112 is divided into the temperature detection unit 121, a correction amount decision unit 122, and a delta value correction unit 123.

The temperature detection unit 121 detects ambient temperature of the input device 1, based on the output value of a temperature detection element provided in the input device 1. As the temperature detection element, a dummy node provided for detecting the temperature, a temperature detection IC having a thermistor mounted therein, or the like may be used. For example, the temperature detection unit 121 can detect the ambient temperature of the input device 1, based on the base signal value at a dummy node, which is supplied from the capacitance detection unit 111.

The correction amount decision unit 122 decides the correction amount to be applied to a delta value based on the detected temperature. As the correction amount, different values may be set for each group made of nodes having similar load sensitivity characteristics. The correction amount decision unit 122 can decide a correction amount that corresponds to the node corresponding to the key based on information regarding the specified key supplied from the key specifying unit 113. In the following description, as an example of the correction amount, the decision of a scale factor (ratio of a detected current delta value to a delta value considered to be obtained after correction) to be applied to a delta value by the correction amount decision unit 122 will be described. The exemplary embodiment is not limited to this example. Other values including a difference between a detected current delta value and a delta value considered to be obtained after correction may be used as an example of the correction amount. When other operation input values than a delta value are intended to be a target to be corrected, the correction amount decision unit 122 may decide a correction amount corresponding to the other operation input values.

The delta value correction unit 123 (corresponding to the operation input value correction unit according to the exemplary embodiment of the present disclosure) corrects the delta value detected by the capacitance detection unit 111 using the decided scale factor. For example, the delta value correction unit 123 can correct the delta value by multiplying the delta value that is detected by the capacitance detection unit 111 by the scale factor that is decided by the correction amount decision unit 122. The delta value corrected by the delta value correction unit 123 may be a value obtained by considering the temperature dependence, that is, a delta value subjected to the temperature compensation. The delta value correction unit 123 supplies the corrected delta value to the input state determination unit 114. When other operation input values than a delta value are intended to be a target to be corrected, the delta value detected by the capacitance detection unit 111 is converted into another operation input value, and then the other operation input value may be corrected using the correction amount corresponding to the other operation input value, which is decided by the correction amount decision unit 122.

The respective functions of the temperature compensation unit 112 (temperature detection unit 121, the correction amount decision unit 122, and the delta value correction unit 123) will be again described in more detail in item 4 “Temperature detection process” and item 5 “Correction scale factor decision process” described later.

The input state determination unit 114 determines an input state of a key corresponding to a node based on a delta value that is detected at each node and is subjected to the temperature compensation. The determination of an input state may be necessary to determine whether an input state for each key is KEY ON state based on the delta value subjected to the temperature compensation. The process performed by the input state determination unit 114 corresponds to the input state determination process described above.

In the input state determination process, the input state of a key may be determined based on an operation input value at each node. As an operation input value, a delta value, a differential delta value that is a differential value of a delta value, and/or a normalized delta value obtained by normalizing a delta value may be used. When a plurality of nodes are provided in one key, the input state determination process may be performed based on statistics such as the sum or average value of a delta value, a differential delta value and/or a normalized delta value. The differential delta value may be a value obtained by differentiating a detected delta value (that is, raw data or a value obtained by amplifying it appropriately) or may be a value obtained by differentiating a normalized delta value. In the following description, the term “differential delta value” may refer to a differential value of a delta value or a differential value of a normalized delta value.

Specifically, the input state determination process determines whether an operation input value satisfies a predetermined condition (or input state determination condition). If it is determined that an operation input value satisfies the input state determination condition, the input state of a key corresponding to a node from which the operation input value is detected (calculated) is determined to be a KEY ON state. On the other hand, if it is not determined that an operation input value satisfies the input state determination condition, the input state of a key corresponding to a node from which the operation input value is detected (calculated) is determined to be in a KEY OFF state. The input state determination condition may be individually set for each key. The input state determination unit 114 can perform the input state determination process using the input state determination condition that is set for the specified key, based on information regarding the key specified by the key specifying unit 113. For example, the input state determination unit 114 refers to the above-described storage device in which the input state determination condition that is set for each key is stored, and thus the input state determination unit 114 can acquire information regarding the input state determination condition that is set for each key and perform the input state determination process.

For example, the input state determination unit 114 compares the operation input value with a predetermined threshold to determine an input state. Specifically, if the operation input value is greater than the predetermined threshold, the input state determination unit 114 determines that the input state of the key corresponding to a target node is the KEY ON state. On the other hand, if the operation input value is less than or equal to the predetermined threshold, the input state determination unit 114 determines that the input state of the key corresponding to a target node is in the KEY OFF state.

The threshold used to determine whether it is in the KEY ON state and the threshold used to determine whether it is in the KEY OFF state may be the same value or different one. When the threshold used to determine whether it is in the KEY ON state is different from the threshold used to determine whether it is in the KEY OFF state, it is possible to prevent so-called chattering, thereby improving the usability.

The input state determination unit 114 determines an input state for each key. However, for example, when a plurality of nodes are associated with a single key, the input state may be determined if an operation input value at any one node included in the key satisfies an input state determination condition (that is, determination by an “OR” operation). Further, the input state may be determined if an operation input value at all the node included in the key satisfies an input state determination condition (that is, determination by an “AND” operation). The input state determination condition may be set for each key in an optional way as necessary. For example, an input state for a certain key may be determined by determination of an “OR” operation, an input state for other keys may be determined by determination of an “AND” operation. The threshold to be compared with the operation input value may be a different value for each key. The input state determination condition for each key may be set appropriately in consideration of the frequency the use of a key or the detection accuracy based on the position in which the key is arranged.

The term “less than or equal to” and “more than” are used herein to describe the magnitude relation between an operation input value and a threshold, these terms are intended to be illustrative and are not restrictive of the boundary condition when comparing an operation input value and a threshold. In the exemplary embodiment, when an operation input value is equal to the threshold, the method of how to determine the magnitude relations may be set in an optional way. The term “less than or equal to” used herein can be substantially the same meaning as the term “less than”, and the term “greater than” can be substantially the same meaning as the term “greater than or equal to” as used herein.

The input state determination process performed by the input state determination unit 114 is not limited to the above-described example. The input state determination unit 114 may perform various input state determination processes, which is known in the art and is used in the technical field of a common touch panel keyboard.

The input state determination unit 114 supplies information regarding a results obtained by determination of an input state for each key to the input state setting unit 115. The input state setting unit 115 sets an input state for each key based on the determination results of an input state obtained by the input state determination unit 114. The input state setting unit 115 sets an input state for each key as one of KEY ON state and KEY OFF state, depending on the determination results of the input state. The input state setting unit 115 transmits information indicating the content of a key to a connection device via the interface IC 140. The content is associated with the key that is set as the KEY ON state. The connection device regards the received information relevant to the key as an input value. The input state setting unit 115 may transmit the results obtained by performing the input state determination process of all the keys to the interface IC 130 in the subsequent stage, and then only information associated with a key determined to be in the KEY ON state may be extracted from among the transmitted results by any configuration (for example, a connection device) succeeding to the interface IC 130.

The functional configuration of the input detection system according to the exemplary embodiment has been described with reference to FIG. 9. It is possible to install a computer program, which is prepared for implementing the functions of the input detection system 2 according to the exemplary embodiment as described above, on a personal computer. It is possible to provide a computer-readable recording medium to store such a computer program. A recording medium includes, for example, a magnetic disk, an optical disk, a magneto-optical disk, and a flash memory. A computer program may be downloaded via a network, without using a recording medium.

### 4. Temperature Detection Process

In the item 4 “Temperature detection process” and item 5 “Correction scale factor decision process”, the respective functions of the temperature compensation unit 112 shown in FIG. 9 will be described in detail. The function of the temperature detection unit 121 described above is first described.

### 4-1. Temperature Detection Process Using Dummy Node

As described with reference to FIG. 6, a base signal value at each node of the input device 1 has the temperature dependence. Thus, with the use of temperature dependence, it is possible to measure the ambient temperature by detecting a base signal value at each node.

However, when a node disposed in the key region 10a (node disposed in a region in which a keystroke is actually performed) is used to detect temperature, the key region 10a and the node being in contact with the finger of the user at the time of operation input have increased temperature, and thus inaccurate ambient temperature may be detected. According to the study of the inventors, when the hand is placed in a region on the operation member 10, which corresponds to a position at which a node is disposed, it is found that a significant difference occurs between the temperature detected from a base signal value at the node and actual ambient temperature. Thus, according to the exemplary embodiment, a dummy node for temperature detection (that is, a capacitive element for temperature detection) provided in a region away from the key region 10a is disposed in a region that is considered to be difficult to contact with the hand of the user in the input device 1, and then the temperature is detected based on the base signal value at the dummy node.

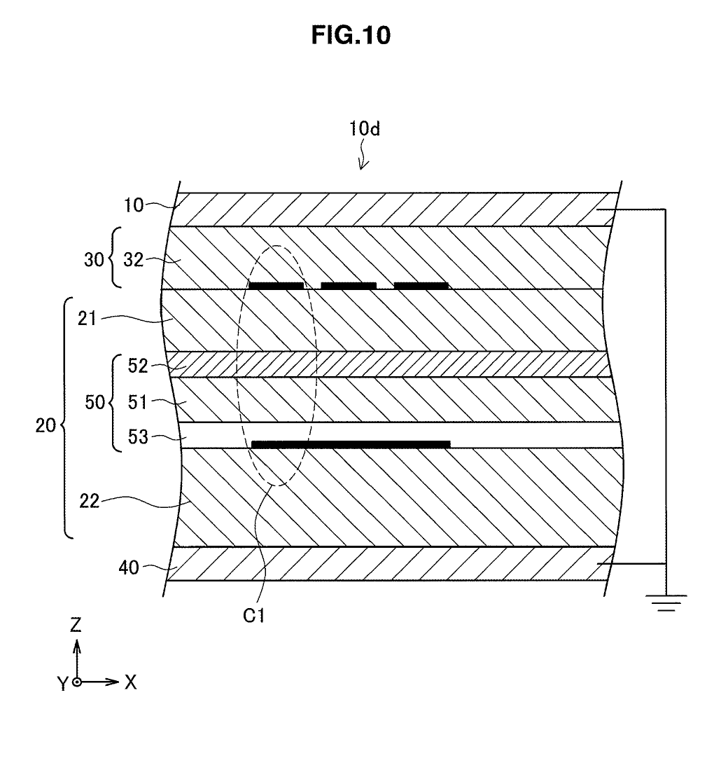

The configuration of a dummy node will be described with reference to FIG. 10. FIG. 10 is a schematic sectional view illustrating an exemplary configuration of a dummy node used for temperature detection. FIG. 10 illustrates a sectional view taken along the X-Z plane in the input device 1, which is similar to the FIG. 2 described above, and illustrates schematically the aspect of the section of a region corresponding to a dummy node.

Referring to FIG. 10, a dummy node region 10d has a structure in which the space 33 and the space 62 of the key region 10a shown in FIG. 2 are filled with another layer. The space 33 is defined by the first support 30. The space 62 is defined by the second support 60. In this way, there is originally no region that is easy to be deformed due to the pressing at the time of keystroke (that is, spaces 33 and 62) in the dummy node region 10a, and a change in the base signal value is less likely to occur at a node by the fact that the dummy node region 10d is deformed for some reason, and thus it is possible to enhance robustness at the time of the temperature detection. The capacitive element C1 included in the dummy node region 10a serves as a dummy node, and the temperature is detected based on a base signal value of the capacitive element C1. The dummy node region 10d shown in FIG. 10 includes layers that are similar to the layers included in the key region 10a shown in FIG. 2, and thus the detailed description thereof will be omitted.

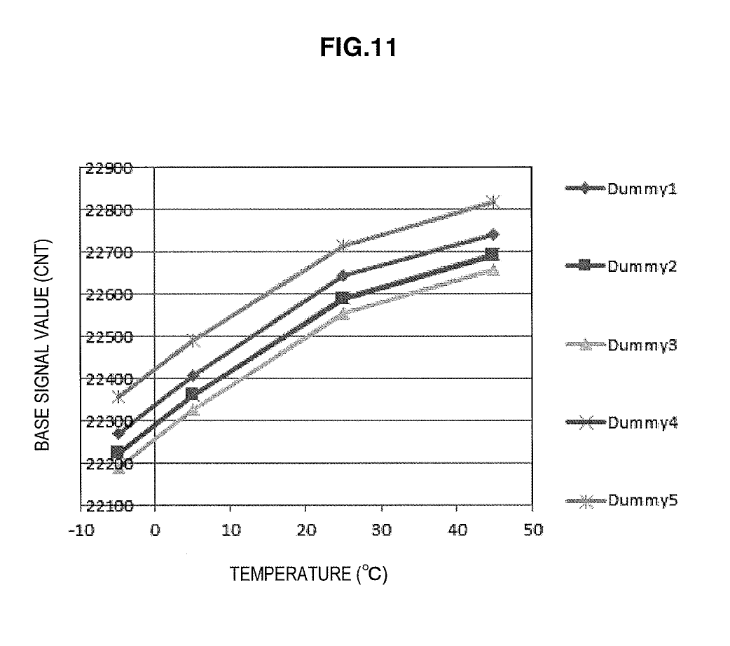

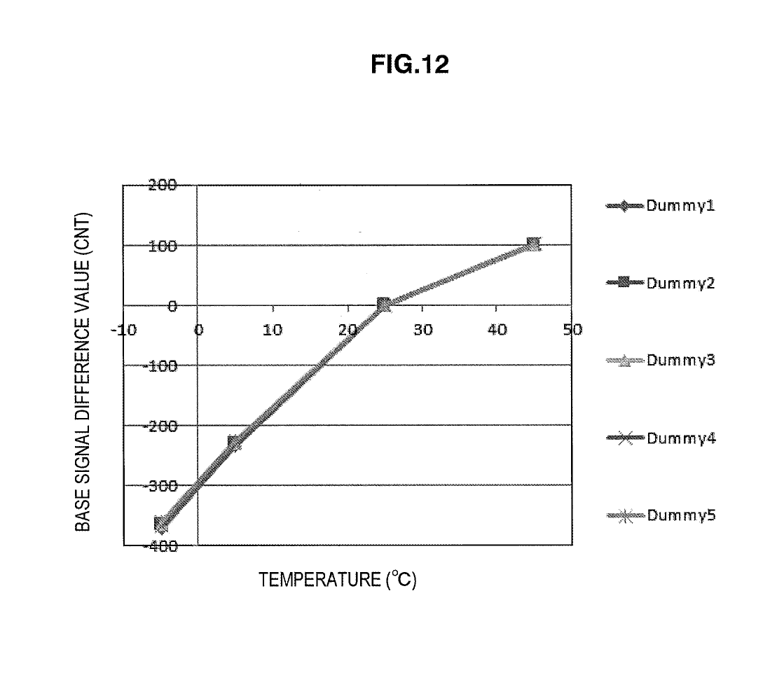

When variations in temperature characteristics between dummy nodes are large, it is likely to obtain low accuracy of temperature detection using a dummy node. The inventors have conducted the experiment to measure the temperature dependence of the base signal values for a plurality of dummy node and to investigate its variation. The results of investigation for the temperature characteristics are illustrated in FIGS. 11 and 12. FIGS. 11 and 12 are graphs showing the temperature characteristics of a dummy node. In FIG. 11, the horizontal axis represents ambient temperature, the vertical axis represents a base signal value of a dummy node, and the relationship between the two is plotted. In FIG. 12, the horizontal axis represents ambient temperature that is similar to FIG. 11, the vertical axis represents a difference value between a base signal value of a dummy node and a base signal value at ordinary temperature (25° C.), and the relationship between the two is plotted.

With reference to FIG. 11, it is found that a base signal value has a variation between dummy nodes when compared at the same temperature. However, as shown in FIG. 12, in terms of a temperature (for example, 25° C. in the example shown in FIG. 12) that is set as a reference and a difference of a base signal value, it is found that the temperature dependence of a base signal value has substantially similar property at each dummy node. FIGS. 11 and 12 illustrate the results obtained from only five dummy nodes to prevent the figures from being complicated, but it is similarly found that the temperature is detectable with a resolution of approximately six degrees (±3 degrees) by a dummy node in the input device 1 used in the experiment as a result of measuring temperature dependence of the base signal value with respect to the increased number of dummy nodes as well. For reference, as a commercially available temperature detection IC (for detection of temperature using a thermistor element), there may be a resolution of ±3.0 degrees for B grade and a resolution of ±4.0 degrees for C grade, according the specifications. In this way, it is found that the dummy node of the input device 1 used in the experiment can serve as a temperature sensor having the property equivalent to a commercially available temperature detection IC.

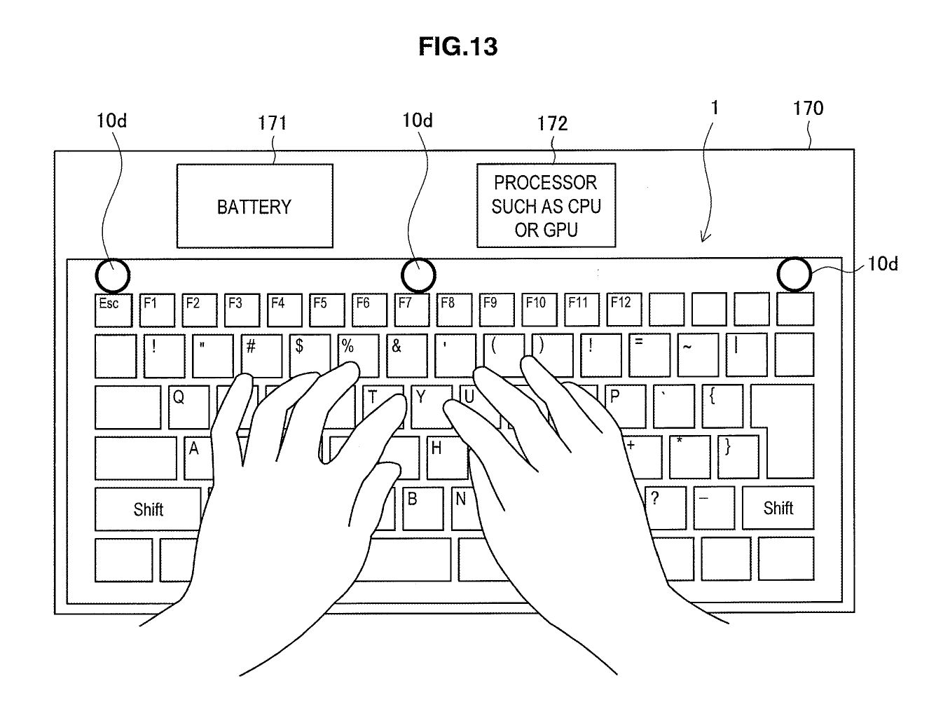

As described above, it is desirable to dispose a dummy node at a portion that is not in contact with the hand of the user as much as possible. An exemplary arrangement of a dummy node in the input device 1 according to the exemplary embodiment will be described with reference to FIG. 13. FIG. 13 is a schematic diagram illustrating an exemplary arrangement of a dummy node in the input device 1.

As illustrated in FIG. 13, the input device 1 according to the exemplary embodiment may be incorporated into a housing 170. The housing 170 may incorporate structural components including a processor 172 (corresponding to the controller IC 110 or the main MCU 120 shown in FIG. 8) for detecting a key input through the input device 1, such as central processing unit (CPU) and graphics processing unit (GPU), and a battery for supplying the power to the processor 172, as well as the input device 1.

FIG. 13 illustrates an example of a position at which the dummy node region 10d is preferably provided in the input device 1. For example, the dummy node region 10d may be preferably disposed in a region corresponding to an end on the far side, which is considered that the user's hand is not placed on the input device 1 in normal use. It is preferable that the dummy node region 10d is disposed in a region sufficiently away from an element that is likely to generate heat (that is, a region unaffected by heat generated by other elements), such as the battery 171 and the processor 172.

As illustrated in FIG. 13, when the plurality of dummy node region 10d are provided in the input device 1, it is possible to enhance robustness at the time of the temperature detection by detecting temperature using base signal values at the plurality dummy node. For example, the temperature may be detected based on an average value of the base signal values detected at the plurality of dummy node.

For example, the temperature may be detected based on a statistical value of a base signal value remained by excluding a value that is considered to be abnormal from among the base signal values at a plurality of dummy nodes. Specifically, when there are three dummy nodes, a process for calculating a difference value between base signal values at two dummy nodes out of these three dummy nodes is performed with respect to a combination of all the dummy nodes. If all of the calculated difference values are less than or equal to a predetermined threshold, the three base signal values are all considered to be valid, and thus the temperature is detected based on the statistical value of the three base signal values. On the other hand, if a difference value between one value (referred to as “Sig1”) of three base signal values and the other two ones of them is greater than a predetermined threshold, a dummy node at which Sig1 is detected is likely to be warmed by the hand or the like, and thus Sig1 is considered to be an abnormal value. Thus, the temperature is detected based on the statistical value of the other two base signal values excluding Sig1. Furthermore, if all of the difference values are greater than a predetermined threshold, it is difficult to determine which base signal value is an abnormal value, and thus it is preferable to interrupt the temperature detection process and then to resume the temperature detection process after a predetermined period has elapsed. In this case, the temperature detected by previously performed the temperature detection process may be used without any modification.

According to the exemplary embodiment, it is possible to detect the temperature based on a base signal value at a dummy node by allowing the temperature detection unit 121 shown in FIG. 9 to perform the above-described process. The information regarding the temperature dependence of a base signal value at a dummy node as shown in FIG. 12 may be previously stored in a storage device (not shown in FIG. 9) provided in the input detection system 2 in the form of a table. Furthermore, the storage device stores information regarding a base signal value at each dummy node at ordinary temperature (for example, 25° C.). The temperature detection unit 121 refers to the storage device, calculates a difference value between a base signal value detected at a dummy node and a base signal value at ordinary temperature, and compares the difference value with the table, and thus it is possible to detect the temperature.

The temperature detection unit 121 may only perform a calculation of a difference value between a base signal value detected at a dummy node and a base signal value at ordinary temperature. The temperature detection unit 121 may not perform the process for converting the difference value into actual ordinary temperature. The relationship shown in FIG. 12 shows that the difference value between ordinary temperature and a base signal value and ambient temperature have a one-to-one correspondence relationship, and thus the temperature is actually detected at the stage of calculating the difference value between ordinary temperature and the base signal value. In this way, the difference value between ordinary temperature and the base signal value is a value that is an index indicating the ambient temperature, and thus, in the exemplary embodiment, the temperature detection process performed by the temperature detection unit 121 may be a process for calculating the difference value between ordinary temperature and the base signal value. As described later, in the correction amount decision unit 122 in the subsequent stage, by referring to the table indicating the relationship between ambient temperature and the correction amount corresponding to the ambient temperature, the correction amount corresponding to the ambient temperature is decided. The table may show the relationship between actual ambient temperature and the correction amount and may show the relationship between the correction amount and the difference value between ordinary temperature and the base signal value. The temperature detection unit 121 can detect the temperature in the form that is used in the process of deciding the correction amount performed by the correction amount decision unit 122.

The temperature detection process using a dummy node has been described. As described above, in the temperature detection process according to the exemplary embodiment, a dummy node for temperature detection is provided in the input device 1 and the temperature is detected based on a base signal value at a dummy node. As a dummy node, for example, a surplus node (redundant node) can be used in the input device 1, and thus it is possible to reduce the increase in manufacturing cost of the input device 1. Moreover, it is possible to enhance the accuracy of temperature detection by devising the arrangement position of a dummy node or by using the base signal value at a plurality of dummy nodes.

### 4-2. Temperature Detection Process Using Temperature Detection IC

In the exemplary embodiment described above, although the temperature is detected using a dummy node, the exemplary embodiment is not limited to this example. According to the exemplary embodiment, the temperature may be detected using a temperature detection IC having a temperature detection element such as a thermistor element mounted thereon.

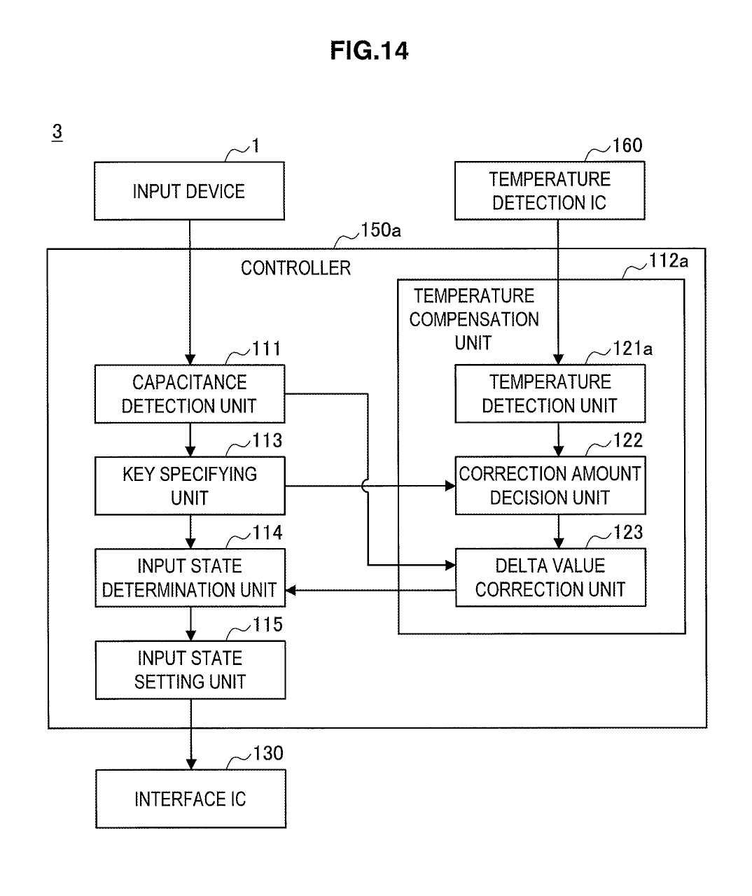

The functional configuration of the input detection system according to a modification of detecting the temperature using a temperature detection IC will be described with reference to FIG. 14. FIG. 14 is a functional block diagram illustrating an example of the functional configuration of the input detection system according to the modification of detecting the temperature using a temperature detection IC.

Referring to FIG. 14, an input detection system 3 according to the modification includes, as its functions, a capacitance detection unit 111, a temperature compensation unit 112a, a key specifying unit 113, an input state determination unit 114, and an input state setting unit 115. The input detection system 3 shown in FIG. 14 may have the substantially same functional configuration as that of the input detection system 2 shown in FIG. 9, except for the temperature detection unit 121a of the temperature compensation unit 112a. Thus, the function of the temperature detection unit 121a is mainly described, which is different from the input detection system 2. In FIG. 14, for the sake of convenience, the respective functions shown to be executable in a controller 150a (corresponding to the information processing device according to the exemplary embodiment of the present disclosure) may be implemented by allowing a processor corresponding to the controller IC 110 and the main MCU 120 shown in FIG. 8 to be executed according to a predetermined program, which is similar to the input detection system 2.

Referring to FIG. 14, in the modification of the present disclosure, the temperature detection unit 121a acquires a base signal value at a dummy node not from the capacitance detection unit 111 but from the temperature detection IC 160 attached to a predetermined portion of the outer surface of the input device 1. The temperature detection IC 160 is configured to include a thermistor element, and supplies a voltage value of the thermistor element to the temperature detection unit 121a. The information regarding the relationship between temperature and a voltage value of the thermistor element in the temperature detection IC 160 may be previously stored in a storage device (not shown in FIG. 14) provided in the input detection system 3 in the form of a table or a predetermined relational expression. The temperature detection unit 121a can detect the temperature by referring to the storage device, converting the voltage value of the thermistor element into a digital value by an analog-to-digital converter (ADC), and converting the digital value into temperature based on the table or predetermined relational expression.

The temperature detection unit 121a supplies the information regarding the detected temperature to the correction amount decision unit 122. Other processes are similar to that of the input detection system 2, and thus the detailed description thereof will be omitted.

The modification of the present disclosure of detecting the temperature using the temperature detection IC 160 has been described. As described above, according to the exemplary embodiment, as the temperature detection element for detecting temperature, a dummy node may be used or the temperature detection IC 160 may be used. In either case, the temperature compensation process may be performed with respect to a delta value in the temperature detection unit 121 or 121a. In the above example, the configuration using the thermistor element is employed as the temperature detection IC 160, but the exemplary embodiment is not limited to this example. The configuration for detecting temperature using other methods may be employed as the temperature detection IC 160. The temperature detection unit 121a can convert the value outputted from the temperature detection IC 160 into appropriate temperature depending on the performance or specifications of the temperature detection IC 160.

### 5. Correction Scale Factor Decision Process

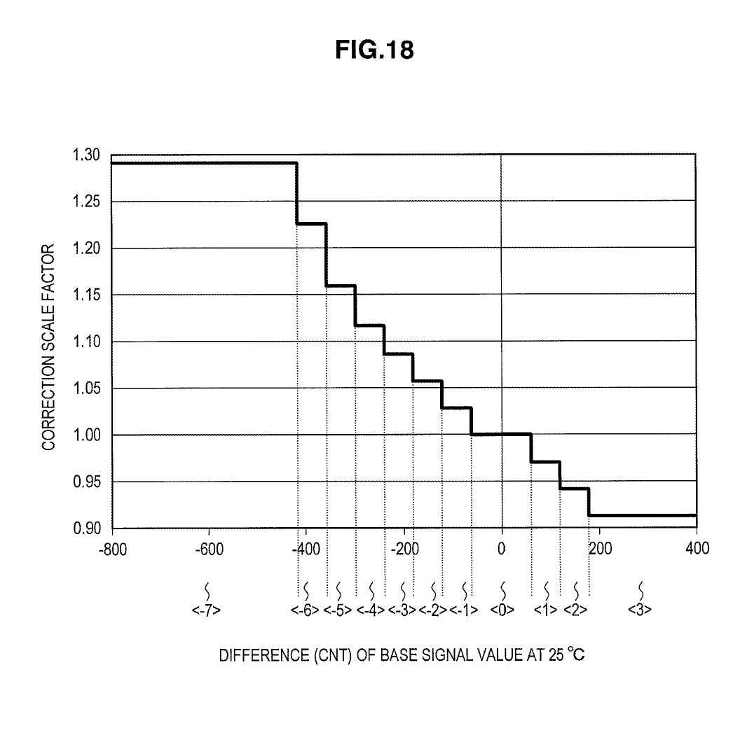

The function of the correction amount decision unit 122 described above with reference to FIG. 9 will be described. The function of the delta value correction unit 123 will be also described. According to the exemplary embodiment, as shown in FIG. 18 described later, a table indicating a scale factor for a delta value depending on temperature (also referred to as “delta value correction table” hereinafter) may be previously stored in each of the input devices 1. The process performed by the correction amount decision unit 122 at the time of an actual keystroke may be a process for deciding a scale factor that is used for a delta value correction table shown in FIG. 18 based on the temperature detected by the temperature detection unit 121. Prior to the description of the process performed by the correction amount decision unit 122 at the time of actual use (keystroke), a method of setting the delta value correction table illustrated in FIG. 18, that is, a method of setting a scale factor depending on the temperature.

### 5-1. Decision of Reference Condition

It is necessary to decide a condition that acts as a reference of correction to set a scale factor. The delta value under the reference condition is an ideal, “desirable delta value”, and thus, when a scale factor is to be set, a scale factor is intended to be set in a manner that the corrected delta value is a delta value under the reference condition.

For example, it is assumed that the ambient temperature is ordinary temperature (25° C.). In other words, the correction scale factor is considered to be set in a manner that the corrected delta value approaches the delta value at 25° C. as much as possible. In this case, ideally, for example, the temperature dependence of the base signal value at each node is previously acquired, and the correction scale factor for each temperature is preferably set in a manner that the delta value is a value of 25° C. at the reference temperature at each node based on the acquired temperature dependence. However, the previous setting of the correction scale factor for all the nodes in the input device 1 and the correction of the delta value for each node are impractical from the point of view of the number of processing or resources of a processor (for example, processor of the main MCU 120 shown in FIG. 8) necessary to perform the setting process. Thus, in practical, a node to be representative (representative node) is selected and the correction scale factor that is set for the representative node is used, and thus the correction of a delta value is performed for the other nodes. In this case, it is necessary to decide a representative node to be a reference that is used to decide the correction scale factor.

Even in the same nodes, a target to be detected from a delta value (for example, the size of delta value, or temporal variation of a delta value during application of load) varies depending on a load condition of a load applied to a key corresponding to the node. Thus, any correction scale factor for correcting a delta value detected at a certain temperature to a delta value at ordinary temperature may vary depending on a load-bearing condition to a key. The load-bearing condition, which may affect a delta value, includes a value of load, an area of a contact surface between the finger and the key region 10a (for example, use of fingertips (nails) for a keystroke or use of the pad of the finger for a keystroke), a position in the key region 10a of a contact surface between the finger and the key region 10a, and temporal variations of loads during application of load. In this case, it is necessary to decide a load-bearing condition to be a reference for deciding a correction scale factor.

Even when a constant load is applied for a given time, a delta value during the application of load is likely not to be substantially fixed but to vary depending on the characteristics of a node. Thus, it is necessary to decide a point (time) used to measure a delta value under the reference condition in conjunction with the load-bearing condition.

For these representative nodes and load-bearing conditions, in the exemplary embodiment, for example, a reference condition is decided as described later. For a representative node, a plurality of nodes having relatively similar load sensitivity characteristics constitute a group, one node to be a reference is selected for each group, and then the selected node is a representative node. A correction scale factor obtained from the temperature characteristics of a representative node is set as a correction scale factor of a group to which the representative node belongs. The nodes having relatively similar load sensitivity characteristics may include nodes disposed in the same kind of key (keys having similar shape or node arrangement). A key to be a representative out of a group made of the same kind of keys is selected, and a node selected out of the key to be a representative may be a representative node.

For the load-bearing condition, it is assumed that a finger-like tool is intended to be used to make the area and position of the contact surface to the key region 10a substantially constant. The finger-like tool may be a structure in which a urethane sheet having a thickness of approximately three millimeters (3 mm) is attached around a cylindrical member having a diameter of approximately ten millimeters (10 mm). It is based on that a predetermined position in the key region 10a is pressed with a predetermined portion of the tool.

A load value to be a reference is defined as 50 gF, and the time of measuring a delta value under the reference condition is defined, in the state in which a given load is applied for one second (1 sec), as the latter 300 millisecond (300 ms). These conditions are decided from the characteristics of the delta value shown in FIG. 15 described later and FIG. 7 described above. FIG. 15 is a graph diagram showing the relationship between a load value and a delta value. In FIG. 15, the horizontal axis represents a load value applied to the key region 10a, the vertical axis represents a delta value at a node provided in the key region 10a, and the relationship between the two is plotted. FIG. 15 shows characteristics at different temperature scales by using temperature as parameters.

As shown in FIG. 15, in the input device 1 used in the experiment, the electrical characteristics and structural characteristics at each node are adjusted so that a delta value under a load of 30 to 50 gF that may be applied during normal use by the user is not saturated. It is considered that the user is easier to have a feeling of a change in a load as the absolute value of the load value increases (that is, the user is easier to have a feeling of a change in the detection sensitivity of a key input with temperature), and thus a load of 50 gF, which is an upper limit that may be applied in normal use by the user, was employed as a reference.

As shown in FIG. 7 described above, in the input device 1 used in the experiment, although the key region 10a is pressed under a constant load value, it was observed that delta values increase gradually in the middle of pressing a key (during a period from the first time to the second time) at low temperatures (for example, 5° C. or −5° C.). This means that the responsiveness of mechanical deformation of the key region 10a with respect to the load of a load decreases at low temperatures. In consideration of the responsiveness at low temperatures, a delta value, which is substantially fixed and, in the state in which a given load is applied for one second (1 sec), is measured during the latter 300 millisecond, was employed as a reference.

### 5-2. Reverse Correction

As described above, with the decision of a reference condition, it is possible to acquire the temperature dependence of a delta value under the reference condition and to set a correction scale factor using the acquired temperature dependence. It is considered that the correction is performed on a delta value detected at each node actually based on the correction scale factor that is set under the reference condition (that is, an ideal correction scale factor). As described above, the correction scale factor to be set under the reference condition is set based on the temperature dependence of a delta value at a representative node. The delta value at each node is ideally corrected to a delta value at ordinary temperature at the representative node by performing the correction based on the correction scale factor.

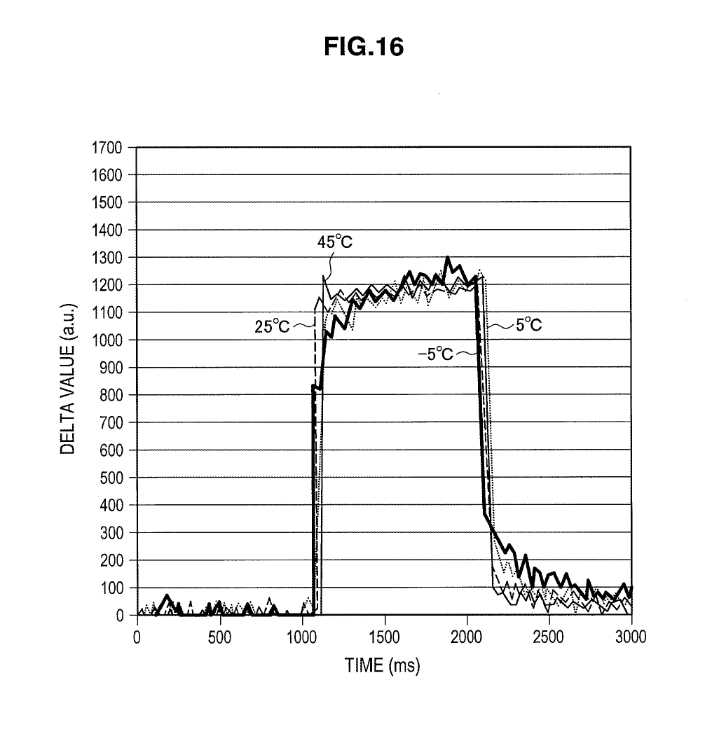

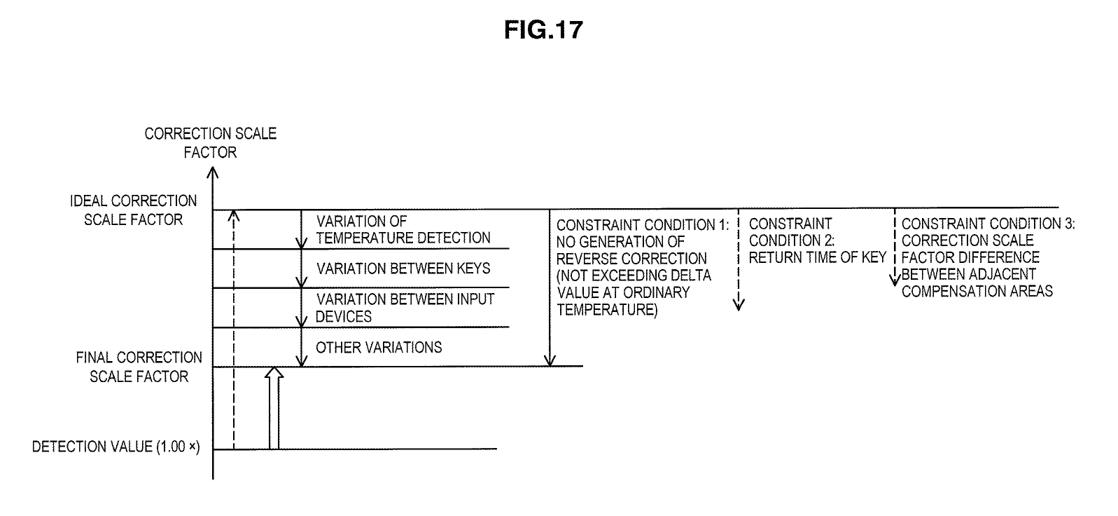

FIG. 16 shows a delta value that is corrected by the ideal correction scale factor. FIG. 16 is a graph diagram showing the relationship between the elapsed time during the application of load and the delta value corrected by the ideal correction scale factor. FIG. 16 is a diagram corresponding to FIG. 17, and the correction performed for a delta value at each time shown in FIG. 7 at the ideal correction scale factor acquired under the reference condition described above is plotted in FIG. 16. As shown in FIG. 16, by using the ideal correction scale factor, it is found that the delta value at each temperature is corrected to be substantially coincident with the delta value at ordinary temperature (25° C.).

However, in practice, it is difficult to consider that the corrected delta value is completely coincident with the delta value at ordinary temperature. This is because there is at least variation in the temperature dependence of a delta value at each node, the load condition of a load, the detection of ambient temperature, or the like. For example, such variation may be occurred in a situation in which the corrected delta value becomes greater than the delta value at ordinary temperature at the representative node.

In the input state determination process of a key, when a delta value is compared with a predetermined threshold and the delta value is greater than the threshold, the input state of the key is determined to be KEY ON state. Thus, when the corrected delta value becomes greater than the delta value at ordinary temperature at the representative node, the determination process of the input state based on the corrected delta value makes it easier that the input state is determined to be KEY ON state. In other words, it may be considered that the sensitivity of detection of the key input is enhanced.

However, for example, in the input device 1, an operation of placing the user's hand on a home position or searching a key in the state in which the user places on the input device 1 (hereinafter, also referred to as “searching operation”) may be performed. Such a searching operation may be an operation specific to a keyboard, which is not performed in the case of applying a touch panel for other purposes. If a key input is detected against the user's intention during the searching operation, the usability will be significantly impaired. Thus, the threshold to be compared with the delta value in the input state determination process is set in a manner that the detection sensitivity of a key is not excessively high, which is intended to prevent an erroneous detection of a key input during the searching operation. Thus, as described above, when there is a key having increased detection sensitivity of an input by performing the temperature compensation, an erroneous detection of a key occurs frequently during the searching operation, resulting in a lack of usability. The correction of a delta value to a value greater than the delta value under the reference condition is herein referred to as “reverse correction” for the sake of convenience.

In the exemplary embodiment, the correction scale factor is reset under a constraint condition that the reverse correction is not occurred, based on a correction scale factor that is set under the reference condition. Specifically, even in a load-bearing situation that may be assumed in normal use, a correction scale factor that provides a margin of preventing the corrected delta value at all the nodes in the input device 1 from being greater than the delta value under the reference condition is set as a final correction scale factor.

A method of setting a correction scale factor in consideration of prevention of reverse correction according to the exemplary embodiment will be described with reference to FIG. 17. FIG. 17 is an explanatory diagram illustrated to describe a method of setting a correction scale factor in consideration of reverse correction according to the exemplary embodiment. In FIG. 17, the vertical axis represents a correction scale factor. FIG. 17 illustrates schematically the relationship between an ideal correction scale factor and a final correction scale factor that is set in consideration of reverse correction.

As shown in FIG. 17, a correction scale factor that is set based on the reference condition (that is, an ideal correction scale factor) is determined. Next, a final correction scale factor is set based on a constraint condition (constraint condition 1) that prevent the occurrence of reverse correction in consideration of various variation factors (for example, variations in the detection of ambient temperature, variations among keys, and variations between input devices).

Other constraint conditions than the constraint condition 1 may be considered when a final correction scale factor is set. In FIG. 17, as an example, a constraint condition regarding the return time of a key (constraint condition 2) and a constraint condition regarding the correction scale factor difference between adjacent compensation areas (constraint condition 3) are illustrated.

The constraint condition regarding the return time of a key mentioned as the constraint condition 2 is a constraint condition relating to the period until the physical deformation of the key region 10a returns to its original state. As described in the item 1 “Configuration of Input Device” described above, in the input device 1, the pressing amount of the operation member 10 to the key region 10a is detected as the capacitance variation amount of the capacitive element C1. For example, even after the finger is removed from the key region 10a, a predetermined magnitude of the non-zero delta value is detected continuously while the operation member 10 is being deformed (that is, during a period in which the distance between the operation member 10 and the electrode board 20 is being reduced).

On the other hand, various types of operating systems (OS) commonly used in a connection device, such as PCs, connected to the input device 1 are often provided with a function (so-called, repeat key function) of performing a continuous input of information corresponding to a key pressed continuously in a keyboard. In the repeat key function, an input operation of a given key is performed continuously when an input state of the key is the KEY ON state for a predetermined period of time. The duration of the KEY ON state in which it is determined that the repeat key function is executed may vary depending on the type of OS, and for example, the duration of a given OS is set to 33 milliseconds. As described above, in the input device 1, a predetermined magnitude of the delta value is detected continuously while the operation member 10 is being deformed even after the finger is removed from the key region 10a. Thus, when it takes a relatively long time until the operation member 10 returns to its original shape, the repeat key function is performed, and thus the same key is likely to be repeatedly inputted against the user's intention.

As shown in FIGS. 7 and 16, when a delta value detected at a temperature (−5° C. or 5° C.) lower than ordinary temperature is corrected to be a delta value at ordinary temperature, the delta value detected at low temperatures is corrected to be a delta value having a large value, and thus the delta value after the second time at which the key pressing to the key region 10a is stopped is corrected to be larger at a predetermined correction scale factor. Thus, when the correction scale factor is large, a delta value after the second time is corrected to be a larger value than necessary, and thus an erroneous input of a key caused due to the repeat key function as described above is more likely to be occurred. In this way, as a constraint condition for an ideal correction scale factor, it is preferable to consider a return time of a key for preventing the erroneous detection of a key caused by the repeat key function. Specifically, when the constraint condition 2 is considered, a correction scale factor is set so that a corrected delta value within a predetermined period from the time when the operation input to the key region 10a is completed does not exceed a predetermined threshold. The predetermined period is the duration of KEY ON state in which the repeat key function is determined to be executed. The predetermined threshold is a threshold that is compared with a delta value and acts as a reference for determining KEY ON state.

The constraint condition regarding a correction scale factor difference between adjacent compensation areas mentioned as the constraint condition 3 is made by considering that the usability decreases because a correction scale factor is significantly changed with a change in temperature. As shown in FIG. 18 described later, in the exemplary embodiment, a correction scale factor may be set stepwise with respect to ambient temperature by providing a plurality of temperature compensation areas depending on the detected temperature and by allowing the correction scale factor to be changed in each temperature compensation area. The setting of the correction scale factor as described above makes it possible to reduce throughput that is necessary for a processor (that is, for example, the main MCU 120 shown in FIG. 8) that performs the temperature compensation process, as compared with the case of setting the correction scale factor to be continuously changed with respect to ambient temperature, resulting in reduction in cost.

However, when a correction scale factor is set stepwise as shown in FIG. 18, if the temperature compensation area is changed with a change in temperature, the correction scale factor will be sharply changed. Thus, the sensitivity of detection of a key input is sharply, significantly changed by a slight change in ambient temperature depending on the amount of change in the correction scale factor, which may lead to an influence on the usability. Thus, as a constraint condition for an ideal correction scale factor, in order to prevent an abrupt change in the sensitivity of detection of a key input, it is preferable to consider a condition that the amount of change in the correction scale factor between compensation areas (correction scale factor difference) does not exceed a predetermined threshold.

In the exemplary embodiment, various constraint conditions as described above are considered, and a final correction scale factor may be set from an ideal correction scale factor based on a constraint condition having the strictest condition. As a constraint condition, a condition that can prevent the decrease in the operational feeling of the user because the sensitivity of detection of a key input is excessively high may be considered. Thus, the temperature correction is performed using a final correction scale factor, and thus it is possible to further improve the usability.

As shown in FIG. 17, in the exemplary embodiment, a final correction scale factor may be a value lower than an ideal correction scale factor by considering various types of constraint conditions. Thus, considering the case of performing the correction on a delta value detected at a certain temperature, a delta value obtained when correction is performed by a final correction scale factor may be a lower value than a delta value obtained when correction is performed by an ideal correction scale factor (delta value that is substantially coincident with the delta value at ordinary temperature). Thus, when the input state is determined based on the delta value obtained when correction is performed by a final correction scale factor, the sensitivity of detection of a key input is likely to be lower than at the time of ordinary temperature. However, as described above, when the sensitivity of detection of a key input is larger than at the time of ordinary temperature by using the corrected delta value, a problem of an erroneous detection of a key input during the searching operation may be occurred. Thus, in the exemplary embodiment, even when the sensitivity of detection of a key input is slightly decreased, the prevention of the situation in which an erroneous detection of a key input during the searching operation can improve the usability from the whole viewpoint. In accordance with such considerations, the constraint condition shown in FIG. 17 is set in a manner that the corrected delta value does not exceed the delta value at ordinary temperature. The example shown in FIG. 17 is merely an example. Any constraint conditions may be set based on other considerations as long as the constraint condition may be set from the viewpoint of improving the usability. When a final correction scale factor is set based on an ideal correction scale factor, various types of constraint conditions may be appropriately set in a manner to improve the usability by considering various systems to which the input device 1 is applicable.

In the exemplary embodiment, the correction scale factor in which the corrected delta value does not exceed the delta value at ordinary temperature may be applied to a delta value detected at higher temperatures than ordinary temperature. For example, in the example shown in FIGS. 7 and 16, a final correction scale factor is set for the delta value detected at a temperature of 45° C. by making the correction scale factor having a smaller value than one that may be set as an ideal correction scale factor to be a further smaller value by considering various types of constraint conditions.

### 5-3. Setting of Delta Value Correction Table

As described above, in the exemplary embodiment, an ideal correction scale factor is set based on a reference condition, the ideal correction scale factor is changed based on the various constraint conditions, and a final correction scale factor is set. In the exemplary embodiment, the temperature range that is set as an operation guaranteed range of the input device 1 is divided into a plurality of regions (hereinafter referred to as “temperature compensation area”), and a final correction scale factor is set for each temperature compensation area, and thus a delta value correction table that represents a correction scale factor for a delta value in each temperature compensation area is set.

FIG. 18 shows an example of the delta value correction table that is set as described above according to the exemplary embodiment. FIG. 18 is a graph showing an example of the delta value correction table according to the exemplary embodiment.

In FIG. 18, the horizontal axis represents a difference value of a base signal value at a node from a base signal value at a temperature of 25° C., the vertical axis represents a correction scale factor, and the relationship between the two is plotted.

In the example shown in FIG. 18, the difference value of base signal value at a temperature of 25° C. in the horizontal axis is divided into eleven temperature compensation areas, from <−7> to <3>, and a correction scale factor for each temperature compensation area is set. In FIG. 18, the horizontal axis represents a difference value of a base signal value at a temperature of 25° C., but the exemplary embodiment is not limited to this example. The horizontal axis may represent ambient temperature. As described in the above item 4-1 “Temperature detection process using dummy node”, the ambient temperature and the difference value between ordinary temperature and a base signal value have a one-to-one correspondence relationship based on the temperature characteristics at a dummy node as shown in FIG. 12, and thus even when the horizontal axis of the delta value correction table represents either one value, substantially similar delta value correction table may be set. As shown in FIG. 18, when the horizontal axis of the delta value correction table represents a difference value between ordinary temperature and a base signal value, as described in the above item 4-1 “Temperature detection process using dummy node”, the temperature detection unit 121 may perform only a process for calculating the difference value or may not calculate a value of actual ambient temperature itself, as a temperature detection process. This is because, when the difference value is known, a correction scale factor can be decided using the delta value correction table shown in FIG. 18.

A method of setting a temperature compensation area is not limited to the shown example, and the temperature compensation area may be appropriately set depending on the temperature range that is set as an operation guaranteed range of the input device 1 or the characteristics of a node such as temperature dependence of a base signal value. By setting a temperature compensation area in detail, a correction scale factor for each temperature may be more strictly set, and thus it is expected that the accuracy of correction of delta value (that is, accuracy of temperature compensation) can be improved. However, if a temperature compensation area is excessively set in detail, a load of signal processing during the searching operation becomes large, which necessitates higher throughput for a processor performing the temperature compensation process (for example, processor of the main MCU 120 shown in FIG. 8). As a result, there is concern that cost is increased. Thus, the temperature compensation area may be appropriately set by considering the tradeoff between performance and cost of the main MCU 120 on the premise that a desired accuracy is secured as an accuracy of temperature compensation. If any problem about cost is resolved and a processor having higher throughput can be employed, a correction scale factor that changes continuously (stepless) may be set for ambient temperature. When a correction scale factor that changes continuously (stepless) is set for temperature, the above-described constraint condition 3 is not necessary to be considered.

### 5-4. Process During Temperature Compensation

The delta value correction table as described above is previously set for each input device 1 and is stored in a storage device provided in the input detection system 2. When the temperature compensation is performed on a delta value in actual use, a difference between the detected base signal value and the base signal value a temperature of 25° C. is calculated at a dummy node by the temperature detection unit 121 (that is, this calculation corresponds to a process of detecting current ambient temperature). The correction amount decision unit 122 decides a correction scale factor corresponding to the current ambient temperature based on the calculation result. The correction amount decision unit 122 can decide a temperature compensation area corresponding to the current temperature and a correction scale factor corresponding to the temperature compensation area based on the delta value correction table by referring to the above-described storage device.

The correction amount decision unit 122 supplies information regarding the decided correction scale factor to the delta value correction unit 123. The delta value correction unit 123 corrects a delta value detected at a node corresponding to a pressed key using the decided correction scale factor. Specifically, the delta value correction unit 123 can correct the delta value by multiplying the delta value detected at a node corresponding to a pressed key by the decided correction scale factor. The delta value correction unit 123 supplies the corrected delta value to the input state determination unit 114. In the input state determination unit 114, when the input state determination process is performed based on the corrected delta value, the sensitivity of detection of a key input approaches the sensitivity at a temperature of 25° C. within a range that does not exceed the sensitivity at a temperature of 25° C. to be a reference. As a result, it is possible to prevent the occurrence of a problem caused by excessively high sensitivity and prevent the reduction in the usability due to a change in temperature of the operating environment.

The correction scale factor decision process according to the exemplary embodiment, in particular, the method of setting a delta value correction table that can be previously set has been described. As described above, in the exemplary, at the time of setting a correction scale factor, an ideal correction scale factor is changed based on various types of constraint conditions and a final correction scale factor is set after an ideal correction scale factor is set based on a reference condition. As the constraint condition, a constraint condition that the reverse correction is not occurred, a constraint condition regarding the return time of a key, and/or a constraint condition regarding the correction scale factor difference between adjacent compensation areas may be considered. By setting a correction scale factor in consideration of these constraint conditions, a correction scale factor may be set in a manner that the sensitivity of detection of a key input having a higher degree of usability is implemented. Thus, a delta value detected at the time of a keystroke is corrected using a correction scale factor that is set as described above, and the input state of a key corresponding to the node is determined using the corrected delta value. As a result, even when the temperature of the operating environment changes, the temperature compensation may be implemented in a manner that the usability is not impaired in the input device 1.

### 6. Information Processing Method

### Temperature Compensation Method

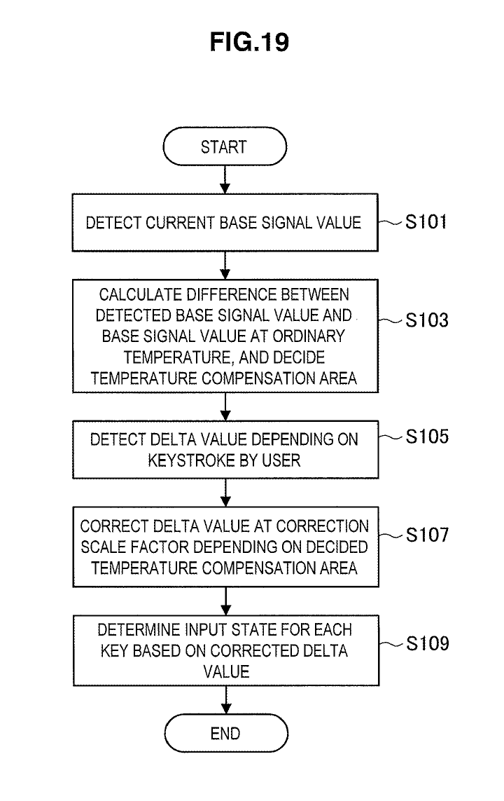

The processing steps of the information processing method performed in the input detection system 2 according to the exemplary embodiment will be described with reference to FIG. 19. FIG. 19 is a flowchart showing processing steps of the information processing method according to the exemplary embodiment. The processing steps shown in FIG. 19 may be executed by the corresponding functions of the input detection system 2 shown in FIG. 9. The flowchart of FIG. 19 mainly illustrates processing steps of the temperature compensation method that is executable by the temperature compensation unit 112, which is a characteristic structure according to the exemplary embodiment, among a series of information processing methods performed in the input detection system 2.

Referring to FIG. 19, in the temperature compensation method according to the exemplary embodiment, a base signal value at a current dummy node is detected (step S101). The process shown in step S101 may be executed, for example, by the capacitance detection unit 111 described above with reference to FIG. 9.

Then, a difference between the detected base signal value at the dummy node and a base signal value at a dummy node at ordinary temperature (25° C.) is calculated, and a temperature compensation are is decided based on the difference (step S103). In step S103, the process of calculating a difference between the detected base signal value al at the dummy node and a base signal value of a dummy node at ordinary temperature may be executed by the correction amount decision unit 122 described above with reference to FIG. 9. The temperature compensation area may be temperature compensation areas of <−7> to <3> in the delta value correction table shown in FIG. 18, and the decision of temperature compensation area allows a correction scale factor to be set accordingly.

Then, a delta value corresponding to the keystroke of the user is detected (step S105). The process in step S105 may be executed by the capacitance detection unit 111 described above with reference to FIG. 9. The delta value detected in step S105 is a delta value to be a target subjected to the temperature compensation.

Then, the delta value detected in step S105 is corrected at the correction scale factor corresponding to the temperature compensation area decided in step S103 (step S107). The process in step S107 may be executed by the delta value correction unit 123 described above with reference to FIG. 9.

Then, an input state of a key corresponding to a node at which the delta value is detected is determined based on the corrected delta value that is corrected in step S107 (step S109). The process in step S109 may be executed by the input state determination unit 114 described above with reference to FIG. 9. Although not shown, at any stage from the process in step S105 to the process in step S109, a process of specifying a key corresponding to node at which the delta value is detected (this process may be executed by the key specifying unit 113 described above with reference to FIG. 9) is performed, and in step S109, the input state of a key is determined based on the input state determination condition that is set for each key. Information associated with a key of the input state determined to be KEY ON state is inputted to a connection device connected to the input device 1. As the input state determination process performed in step S109, various types of process known in the art, which is used in the technical field of a common touch panel keyboard, may be performed.

The processing steps of the information processing method performed by the input detection system 2 according to the exemplary embodiment have been described with reference to FIG. 19.

### 7. Result of Temperature Compensation Process

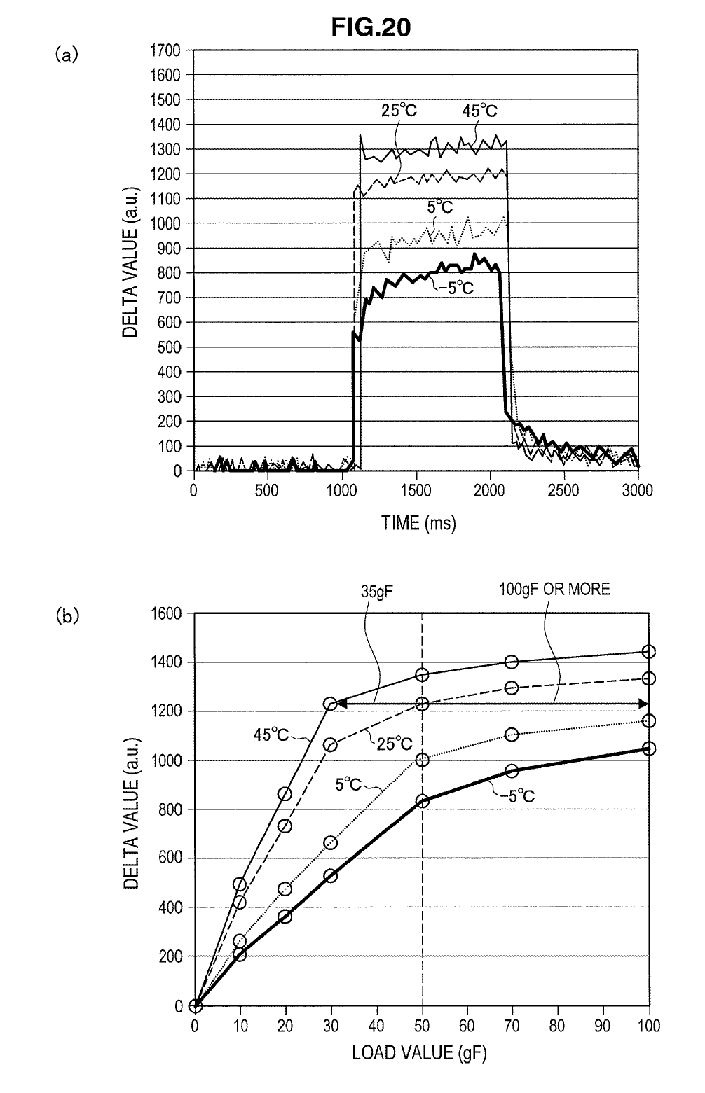

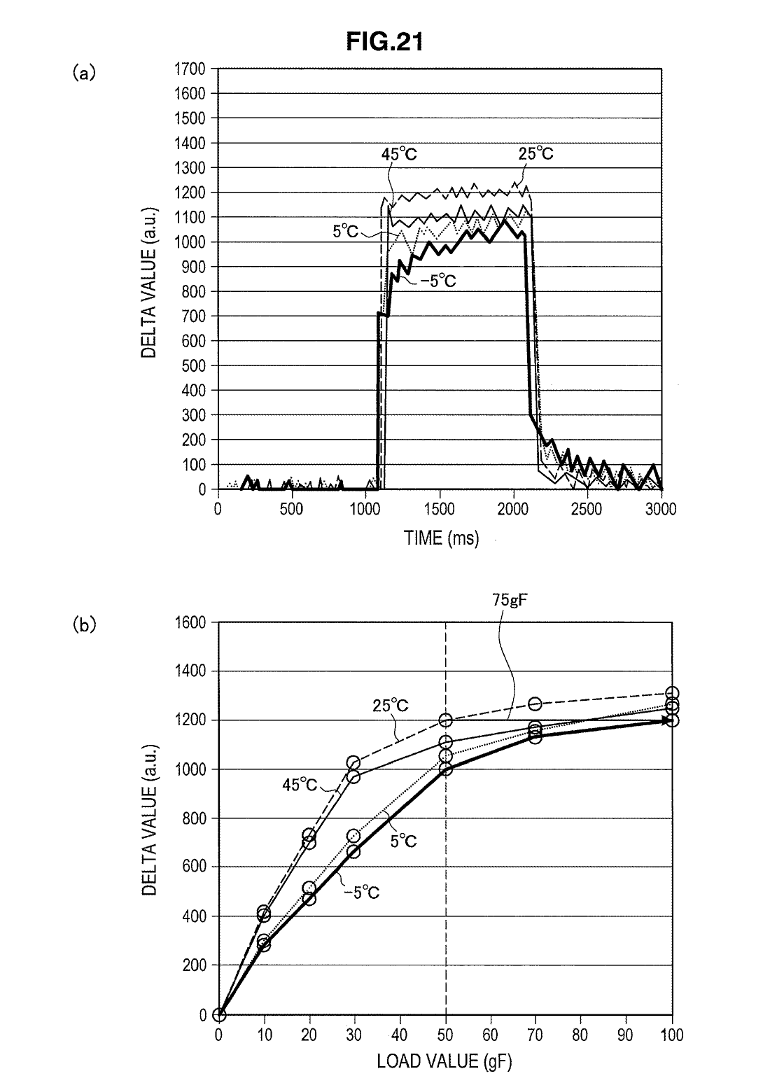

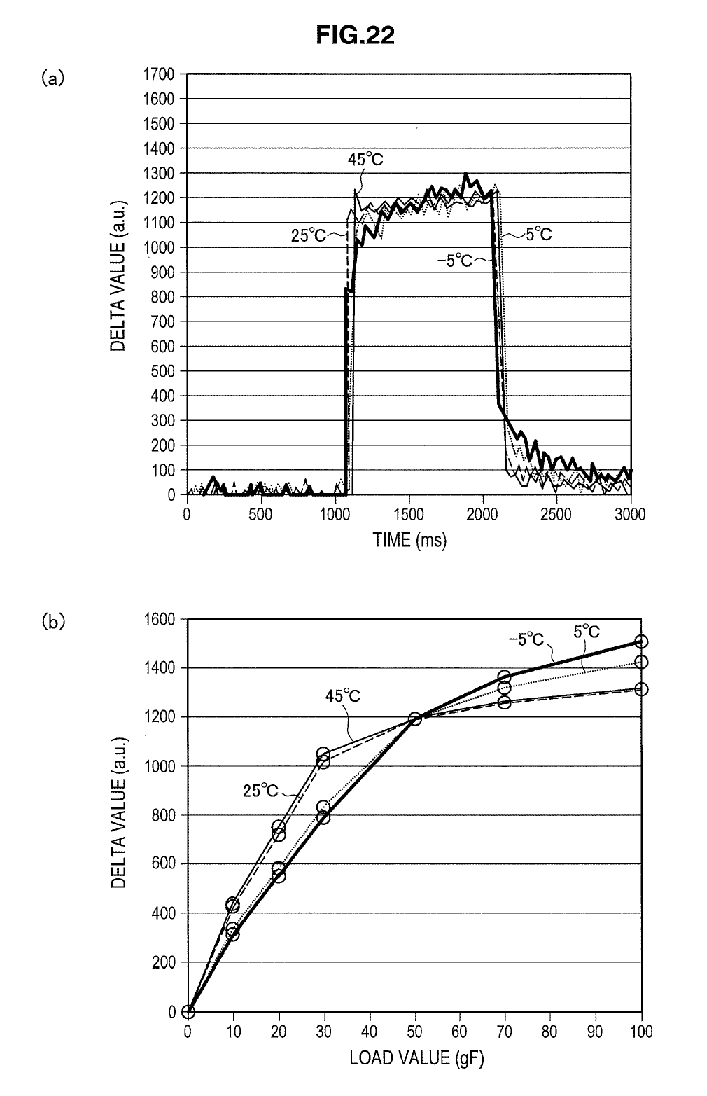

The results obtained by applying the temperature compensation process according to the exemplary embodiment described above to the input device 1 will be described with reference to FIGS. 20 to 22. FIG. 20 is a graph diagram showing load sensitivity characteristics of a delta value of the input device 1 in the case where temperature compensation is not performed. FIG. 21 is a graph diagram showing load sensitivity characteristics of a delta value of the input device 1 in the case where the temperature compensation according to the exemplary embodiment is performed. FIG. 22 is a graph diagram showing load sensitivity characteristics of a delta value of the input device 1 in the case where the temperature compensation is performed at the ideal correction scale factor that is set based on the reference condition.

In FIGS. 20 to 22, two graphs are illustrated. In the figures, (a) is a diagram corresponding to FIGS. 7 and 16 described above, the horizontal axis represents time, the vertical axis represents a delta value detected at a node corresponding to the key region 10a in the input device 1. The relationship between the two is plotted. In the graph of (a) in the figures, the key region 10a is started to be pressed under a predetermined load (for example, 50 gF) using a finger-like tool at predetermined first time, then an operation of releasing the tool from the key region 10a is performed at predetermined second time, and during this operation, temporal variations in delta values at a node corresponding to the pressed key region 10a are illustrated. FIG. 20 (a) is a diagram that reproduces FIG. 7, and FIG. 21 (a) is a diagram that reproduces FIG. 16.

In the figures, (b) is a diagram corresponding to FIG. 15 described above, the horizontal axis represents a load value applied to the key region 10a, the vertical axis represent a delta value at a node provided in the key region 10a, and the relationship between the two is plotted. FIG. 20 (b) is a diagram that reproduces FIG. 15.

Referring to FIG. 20, when temperature compensation is not performed, for example, ambient temperature is 45° C., a delta value equivalent to ordinary temperature is detected only pressing the key region 10 with a small load value of approximately 35 gF (that is, a key input is easy to be detected). When ambient temperature is −5° C. or 5° C., unless the key region 10 is pressed with a large load value of 100 gF and more, a delta value equivalent to ordinary temperature is not detected (that is, a key input is difficult to be detected). In this way, in the case where temperature compensation is not performed, the sensitivity of detection of a key input is increased at high temperatures, and the sensitivity of detection of a key input is decreased at low temperatures. As a result, a keystroke feeling is significantly changed depending on a change in ambient temperature, and thus the usability is likely to be impaired.

Referring to FIG. 22, in the case where temperature compensation is performed using an ideal correction scale factor, although ambient temperature is changed so much, the key region 10a is pressed with a load value of 50 gF that is set as a reference condition, and thus a delta value equivalent to ordinary temperature is detected. However, in the case where temperature compensation is performed using an ideal correction scale factor, all the nodes are not necessarily corrected to have the load sensitivity characteristics similar to the representative node that is set as a reference condition due to various variation factors. For example, when a corrected delta value at a certain node is greater than a delta value at the representative node, it may be considered that the sensitivity of detection of a key input corresponding to the node becomes higher than the sensitivity of detection of a key input corresponding to the representative node. When the sensitivity of detection of a key input is excessively high, an operation in which a key input is not intended, such as an operation of placing the hand in a home position or an operation of searching a key on the input device 1, is likely to make an erroneous detection of a key input, and thus the degree of freedom of operation by the user is undesirably limited.

Therefore, according to the exemplary embodiment, a correction scale factor is set and temperature compensation is performed, based on a constraint condition for preventing the occurrence of such reverse correction. FIG. 21 shows load sensitivity characteristics of a delta value in the case where temperature compensation is performed using a correction scale factor that is set based on a constraint condition for preventing the occurrence of reverse correction. Referring to FIG. 21, when the temperature compensation according to the exemplary embodiment is performed, at any ambient temperatures, the key region 10a is pressed with a large load value of approximately 75 gF, and thus a delta value equivalent to the delta value that can be detected with a load of 50 gF at ordinary temperature is detected. As compared with the case of performing the temperature compensation using an ideal correction scale factor, the load value necessary to obtain a delta value equivalent to that at ordinary temperature is larger, but the result obtained from the this experiment (approximately 75 gF) satisfies the specifications as a product of the input device 1, and it is considered that a significant reduction in the sensitivity of detection of a key input that impairs the usability would not be occurred. On the other hand, an erroneous detection of a key input as described above is prevented, and thus the usability is further improved from the whole viewpoint.

It should be understood by those skilled in the art that various modifications, combinations, sub-combinations and alterations may occur depending on design requirements and other factors insofar as they are within the scope of the appended claims or the equivalents thereof.

In addition, the effects described in the present specification are merely illustrative and demonstrative, and not limitative. In other words, the technology according to the present disclosure can exhibit other effects that are evident to those skilled in the art along with or instead of the effects based on the present specification.

Additionally, the present technology may also be configured as below.

(1) An information processing device including:

a temperature compensation unit configured to correct an operation input value indicating an operation input to each of a plurality of key regions provided on a sheet-like operation member based on ambient temperature of an input device in which the operation input to each of the key regions is detected as a capacitance variation amount of a capacitive element depending on a change in a distance between the key region and the capacitive element, the capacitive element being provided in a manner that the capacitive element corresponds to each of the key regions.

(2) The information processing device according to (1),

wherein the temperature compensation unit includes
a temperature detection unit configured to detect the ambient temperature based on an output value of a temperature detection element provided in the input device,
a correction amount decision unit configured to decide a correction amount for the operation input value based on the detected temperature, and
an operation input value correction unit configured to correct the operation input value using the decided correction amount.
   (3) The information processing device according to (2),

wherein the temperature detection element is a capacitive element for temperature detection that is the capacitive element provided in a region different from the key regions to detect temperature, and

wherein the temperature detection unit detects the ambient temperature based on temperature dependence of a capacitance value of the capacitive element for temperature detection.

(4) The information processing device according to (3),

wherein the capacitive element for temperature detection is provided in a region corresponding to an end portion on a far side when viewed from a user who performs an operation input to the key region in the input device.

(5) The information processing device according to (3) or (4),

wherein the capacitive element for temperature detection is provided in a region unaffected by heat generated from an element provided together with the input device.

(6) The information processing device according to any one of (3) to (5),

wherein a plurality of the capacitive elements for temperature detection are provided, and

wherein the temperature detection unit detects the ambient temperature based on a statistical value of capacitance values of the plurality of capacitive elements for temperature detection.

(7) The information processing device according to any one of (3) to (5),

wherein a plurality of the capacitive elements for temperature detection are provided, and

wherein the temperature detection unit excludes, among capacitance values of the plurality of capacitive elements for temperature detection, a capacitance value in which a difference value from different capacitance values is greater than a predetermined threshold, and detects the ambient temperature based on the different capacitance values.

(8) The information processing device according to any one of (3) to (7),

wherein a space is between the capacitive element for temperature detection and the operation member is filled with another member in a region provided with the capacitive element for temperature detection.

(9) The information processing device according to (2),

wherein the temperature detection element is a temperature detection IC on which a thermistor element is mounted.

(10) The information processing device according to any one of (2) to (9),

wherein the correction amount is set for each temperature compensation area defined depending on the detected ambient temperature in a manner that the correction amount is changed stepwise relative to the ambient temperature.

(11) The information processing device according to any one of (2) to (10),

wherein the correction amount is set in a manner that the corrected operation input value does not exceed an operation input value at temperature to be a reference.

(12) The information processing device according to any one of (2) to (10),

wherein the correction amount is set in a manner that the corrected operation input value does not exceed a predetermined threshold within a predetermined period from a time when the operation input to the key region is completed.

(13) The information processing device according to (10),

wherein the correction amount is set in a manner that a difference of the correction amounts between the temperature compensation areas adjacent to each other does not exceed a predetermined threshold.

(14) An input device including:

a sheet-like operation member that includes a plurality of key regions and is deformable depending on an operation input to the key region;

an electrode board that includes at least one capacitive element at a position corresponding to each of the key regions and is capable of detecting an amount of change in a distance between the key region and the capacitive element as a capacitance variance amount of the capacitive element, the amount of change being dependent on the operation input; and

a controller configured to correct an operation input value indicating an operation input to the key region based on ambient temperature.

(15) An information processing method including:

correcting, by a processor, an operation input value indicating an operation input to each of a plurality of key regions provided on a sheet-like operation member based on ambient temperature of an input device in which the operation input to each of the key regions is detected as a capacitance variation amount of a capacitive element depending on a change in a distance between the key region and the capacitive element, the capacitive element being provided in a manner that the capacitive element corresponds to each of the key regions.

(16) A program for causing a processor of a computer to execute the function of:

correcting an operation input value indicating an operation input to each of a plurality of key regions provided on a sheet-like operation member based on ambient temperature of an input device in which the operation input to each of the key regions is detected as a capacitance variation amount of a capacitive element depending on a change in a distance between the key region and the capacitive element, the capacitive element being provided in a manner that the capacitive element corresponds to each of the key regions.

What is claimed is:

1. An information processing device comprising:
a temperature compensation unit configured to correct an operation input value indicating an operation input to each of a plurality of key regions provided on a sheet-like operation member based on ambient temperature of an input device in which the operation input to each of the key regions is detected as a capacitance variation amount of a capacitive element depending on a change in a distance between the key region and the capacitive element, the capacitive element being provided in a manner that the capacitive element corresponds to each of the key regions.

2. The information processing device according to claim 1,
wherein the temperature compensation unit includes
a temperature detection unit configured to detect the ambient temperature based on an output value of a temperature detection element provided in the input device,
a correction amount decision unit configured to decide a correction amount for the operation input value based on the detected temperature, and
an operation input value correction unit configured to correct the operation input value using the decided correction amount.

3. The information processing device according to claim 2,
wherein the temperature detection element is a capacitive element for temperature detection that is the capacitive element provided in a region different from the key regions to detect temperature, and
wherein the temperature detection unit detects the ambient temperature based on temperature dependence of a capacitance value of the capacitive element for temperature detection.

4. The information processing device according to claim 3,
wherein the capacitive element for temperature detection is provided in a region corresponding to an end portion on a far side when viewed from a user who performs an operation input to the key region in the input device.

5. The information processing device according to claim 3,
wherein the capacitive element for temperature detection is provided in a region unaffected by heat generated from an element provided together with the input device.

6. The information processing device according to claim 3,
wherein a plurality of the capacitive elements for temperature detection are provided, and
wherein the temperature detection unit detects the ambient temperature based on a statistical value of capacitance values of the plurality of capacitive elements for temperature detection.

7. The information processing device according to claim 3,
wherein a plurality of the capacitive elements for temperature detection are provided, and
wherein the temperature detection unit excludes, among capacitance values of the plurality of capacitive elements for temperature detection, a capacitance value in which a difference value from different capacitance values is greater than a predetermined threshold, and detects the ambient temperature based on the different capacitance values.

8. The information processing device according to claim 3,
wherein a space is between the capacitive element for temperature detection and the operation member is filled with another member in a region provided with the capacitive element for temperature detection.

9. The information processing device according to claim 2,
wherein the temperature detection element is a temperature detection IC on which a thermistor element is mounted.

10. The information processing device according to claim 2,
wherein the correction amount is set for each temperature compensation area defined depending on the detected ambient temperature in a manner that the correction amount is changed stepwise relative to the ambient temperature.

11. The information processing device according to claim 2,
wherein the correction amount is set in a manner that the corrected operation input value does not exceed an operation input value at temperature to be a reference.

12. The information processing device according to claim 2,
wherein the correction amount is set in a manner that the corrected operation input value does not exceed a predetermined threshold within a predetermined period from a time when the operation input to the key region is completed.

13. The information processing device according to claim 10,
wherein the correction amount is set in a manner that a difference of the correction amounts between the temperature compensation areas adjacent to each other does not exceed a predetermined threshold.

14. An input device comprising:
a sheet-like operation member that includes a plurality of key regions and is deformable depending on an operation input to the key region;
an electrode board that includes at least one capacitive element at a position corresponding to each of the key regions and is capable of detecting an amount of change in a distance between the key region and the capacitive element as a capacitance variance amount of the capacitive element, the amount of change being dependent on the operation input; and
a controller configured to correct an operation input value indicating an operation input to the key region based on ambient temperature.

15. An information processing method comprising:
correcting, by a processor, an operation input value indicating an operation input to each of a plurality of key regions provided on a sheet-like operation member based on ambient temperature of an input device in which the operation input to each of the key regions is detected as a capacitance variation amount of a capacitive element depending on a change in a distance between the key region and the capacitive element, the capacitive element being provided in a manner that the capacitive element corresponds to each of the key regions.

16. A program for causing a processor of a computer to execute the function of:
correcting an operation input value indicating an operation input to each of a plurality of key regions provided on a sheet-like operation member based on ambient temperature of an input device in which the operation input to each of the key regions is detected as a capacitance variation amount of a capacitive element depending on a change in a distance between the key region and the capacitive element, the capacitive element being provided in a manner that the capacitive element corresponds to each of the key regions.
